(19) United States
(12) Patent Application Publication
(10) Pub. No.: US 2023/0052880 A1
(43) Pub. Date: Feb. 16, 2023

(54) SEMICONDUCTOR DEVICE AND METHOD OF MANUFACTURING SEMICONDUCTOR DEVICE

(71) Applicant: ROHM CO., LTD., Kyoto (JP)

(72) Inventor: Shota IZUMI, Kyoto (JP)

(73) Assignee: ROHM CO., LTD., Kyoto (JP)

(21) Appl. No.: 17/883,159

(22) Filed: Aug. 8, 2022

(30) Foreign Application Priority Data
Aug. 16, 2021 (JP) 2021-132283

(51) Int. Cl. H01L 27/092; H01L 21/8238

(52) U.S. Cl. CPC H01L 27/0922; H01L 27/0928; H01L 21/823807; H01L 21/823814; H01L 21/82385

(57) ABSTRACT

A semiconductor device includes: a semiconductor layer having a first main surface in which a region for a first element is formed; and an element isolation portion configured to partition a first active region in the region for the first element. The first element includes: a first gate electrode, a first gate insulating film, a first-conduction-type first source region and a first-conduction-type first drain region, a first-conduction-type first source extension portion and a first-conduction-type first drain extension portion, and a second-conduction-type second source extension portion and a second-conduction-type second drain extension portion.

### CROSS-REFERENCE TO RELATED APPLICATION

This application is based upon and claims the benefit of priority from Japanese Patent Application No. 2021-132283, filed on Aug. 16, 2021, the entire contents of which are incorporated herein by reference.

### TECHNICAL FIELD

The present disclosure relates to a semiconductor device and a method of manufacturing a semiconductor device.

### BACKGROUND

For example, a method of restricting formation of a divot having a shallow trench isolation (STI) structure is disclosed in related art. This method of the related art includes a step of providing an oxide deposited in a trench formed in a silicon region, a step of oxidizing an upper layer of the silicon region to form a thermal oxide layer on the upper surface of the silicon region, and a step of selectively etching the thermal oxide layer with respect to the deposited oxide.

### SUMMARY

Some embodiments of the present disclosure provide a semiconductor device capable of suppressing a hump phenomenon from occurring in the drain current-gate voltage (Ids-Vgs) characteristics and a method of manufacturing the semiconductor device.

According to one embodiment of the present disclosure, a semiconductor device includes: a semiconductor layer having a first main surface in which a region for a first element is formed; and an element isolation portion configured to partition a first active region in the region for the first element, wherein the first element includes: a first gate electrode extending across the first active region in a first direction; a first gate insulating film formed between the first gate electrode and the semiconductor layer; a first-conduction-type first source region and a first-conduction-type first drain region, which are formed on a surface layer portion of the first main surface and spaced apart from each other by interposing the first gate electrode in a second direction intersecting the first direction; a first-conduction-type first source extension portion and a first-conduction-type first drain extension portion, which extend integrally along the second direction from the first source region and the first drain region, respectively; and a second-conduction-type second source extension portion and a second-conduction-type second drain extension portion, which are selectively formed on an end portion of the first active region and extend integrally along the second direction from the first source region and the first drain region, respectively, and wherein a concentration profile of a second-conduction-type impurity at the end portion of the first active region includes a first section, a second section changing within an impurity concentration lower than an impurity concentration in the first section, and a third section changing within an impurity concentration higher than an impurity concentration in the second section, which are arranged sequentially from the first source region toward the first drain region in the second direction.

### BRIEF DESCRIPTION OF DRAWINGS

The accompanying drawings, which are incorporated in and constitute a part of the specification, illustrate embodiments of the present disclosure.

FIG. 1 is a schematic plan view of a semiconductor device according to an embodiment of the present disclosure.

FIG. 2 is a schematic cross-sectional view of a portion surrounded by two-dot chain line II in FIG. 1.

FIG. 3 is a schematic cross-sectional view of a portion surrounded by two-dot chain line III in FIG. 1.

FIG. 4 is a diagram showing a cross section taken along line IV-IV in FIG. 1

FIG. 5 is a diagram showing a cross section taken along line V-V in FIG. 1.

FIG. 6 is an enlarged view of a portion surrounded by two-dot chain line VI in FIG. 4.

FIGS. 7A and 7B are diagrams showing impurity concentration profiles of a medium withstand voltage p-type channel MOS transistor and a medium withstand voltage n-type channel MOS transistor.

FIG. 8 is a schematic cross-sectional view of a portion surrounded by two-dot chain line VIII in FIG. 1.

FIG. 9 is a schematic cross-sectional view of a portion surrounded by two-dot chain line IX in FIG. 1.

FIG. 10 is a diagram showing a cross section taken along line X-X in FIG. 1.

FIG. 11 is a diagram showing a cross section taken along line XI-XI in FIG. 1

FIGS. 12A and 12B are diagrams showing impurity concentration profiles.

FIG. 13 is a diagram showing static characteristics of a low withstand voltage p-type channel MOS transistor.

FIG. 14 is a flow chart of a semiconductor device manufacturing process.

FIG. 15A is a diagram showing a step related to formation of an element isolation portion.

FIG. 15B is a diagram showing a next step of FIG. 15A.

FIG. 15C is a diagram showing a next step of FIG. 15B.

FIG. 15D is a diagram showing a next step of FIG. 15C.

FIG. 15E is a diagram showing a next step of FIG. 15D.

FIG. 15F is a diagram showing a next step of FIG. 15E.

FIG. 16A is a diagram showing a step related to formation of a p-type DDD region.

FIG. 16B is a diagram showing a step related to formation of the p-type DDD region.

FIG. 16C is a diagram showing a step related to formation of the p-type DDD region.

FIG. 16D is a diagram showing a step related to formation of the p-type DDD region.

FIG. 17A is a diagram showing a step related to formation of an n-type DDD region.

FIG. 17B is a diagram showing a step related to formation of the n-type DDD region.

FIG. 17C is a diagram showing a step related to formation of the n-type DDD region.

FIG. 17D is a diagram showing a step related to formation of the n-type DDD region.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Next, an embodiment of the present disclosure will be described in detail with reference to the accompanying drawings. In the following, the direction in which a gate electrode extends in each transistor is defined as a first direction X, the direction in which a source region and a drain region face each other in each transistor is defined as a second direction Y, and the thickness direction of a semiconductor substrate is defined as a third direction Z. The definitions of the first direction X, the second direction Y, and the third direction Z are not limited thereto. For example, the arrangement direction of a plurality of transistors may be defined as a first direction X, and a direction orthogonal to the arrangement direction may be defined as a second direction Y.

### [Overview of Semiconductor Device 1]

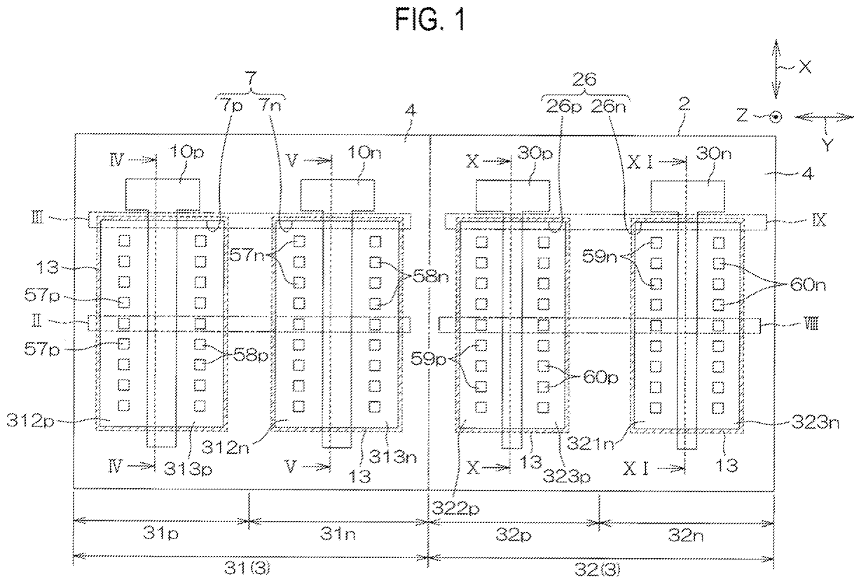

FIG. 1 is a schematic plan view of a semiconductor device 1 according to an embodiment of the present disclosure. Referring to FIG. 1, the semiconductor device 1 is, for example, a composite element in which a plurality of elements is mounted on a common semiconductor substrate, and includes a CMOS area 2. A CMOS transistor 3 is formed in the CMOS area 2. Although not shown in FIG. 1, the semiconductor substrate may include, in addition to the CMOS area 2, for example, a DMOS area in which a DMOS transistor is formed, a bipolar area in which a bipolar transistor is formed, a passive element area in which passive elements such as a resistor element, a capacitor and the like are formed, and the like.

As the CMOS transistor 3, for example, a medium withstand voltage CMOS transistor 31 and a low withstand voltage CMOS transistor 32 may be formed in the CMOS area 2. The medium withstand voltage CMOS transistor 31 may be, for example, a CMOS transistor having a rated voltage of 4.0 V or more and 7.0 V or less. The low withstand voltage CMOS transistor 32 may be, for example, a CMOS transistor having a rated voltage of 1.0 V or more and 4.0 V or less. The rated voltage may be defined to fall within a range of the maximum allowable value of a voltage which is applied between the source and the drain of the medium withstand voltage CMOS transistor 31 and the low withstand voltage CMOS transistor 32. Further, the rated voltages of the medium withstand voltage CMOS transistor 31 and the low withstand voltage CMOS transistor 32 may be rephrased as the withstand voltages of the medium withstand voltage CMOS transistor 31 and the low withstand voltage CMOS transistor 32.

The medium withstand voltage CMOS transistor 31 includes a medium withstand voltage p-type channel MOS transistor 31p and a medium withstand voltage n-type channel MOS transistor 31n. The low withstand voltage CMOS transistor 32 includes a low withstand voltage p-type channel MOS transistor 32p and a low withstand voltage n-type channel MOS transistor 32n. The individual MOS transistors 31p, 31n, 32p, and 32n are electrically isolated from other elements by an element isolation portion 4.

### [Structure of Medium Withstand Voltage CMOS Transistor 31]

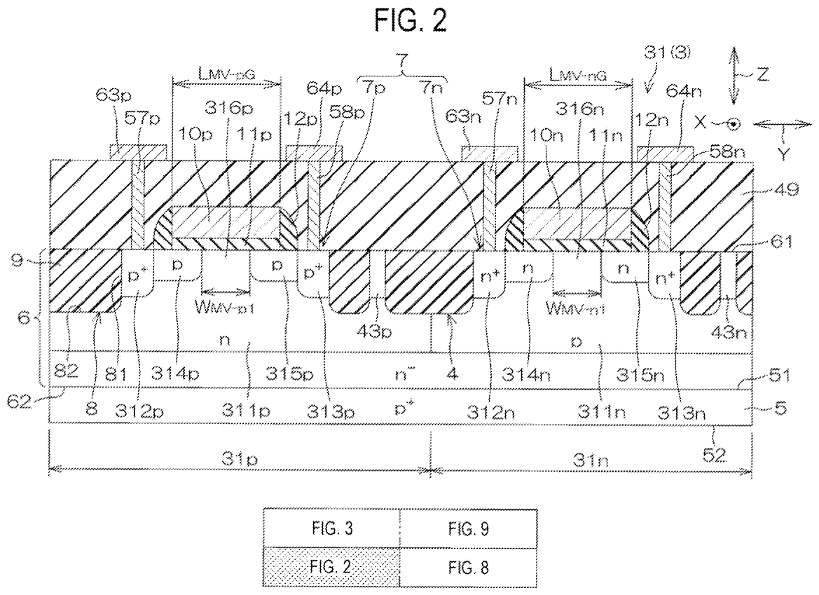

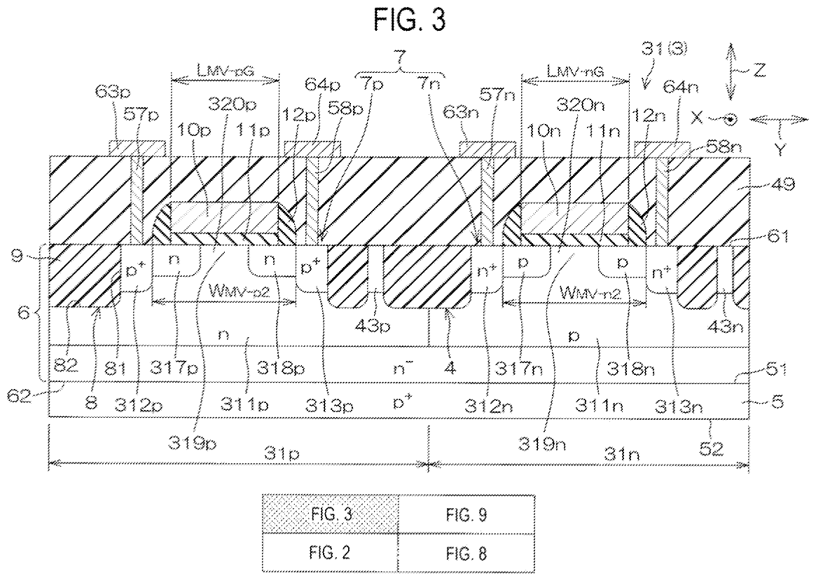

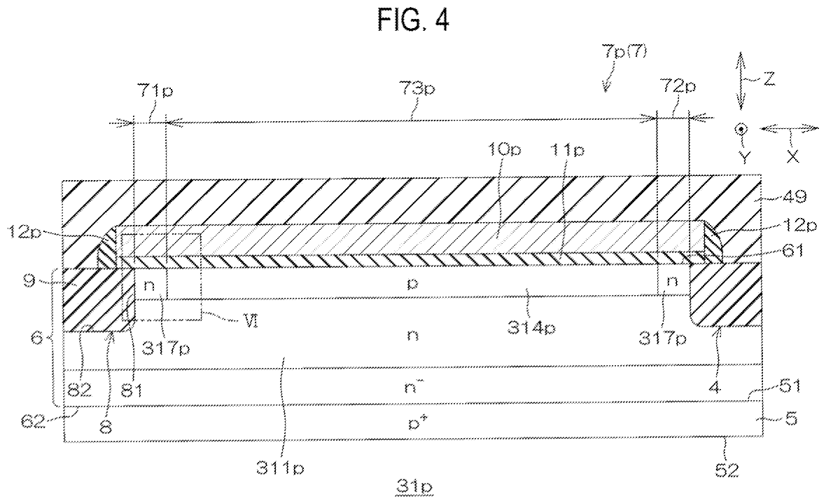

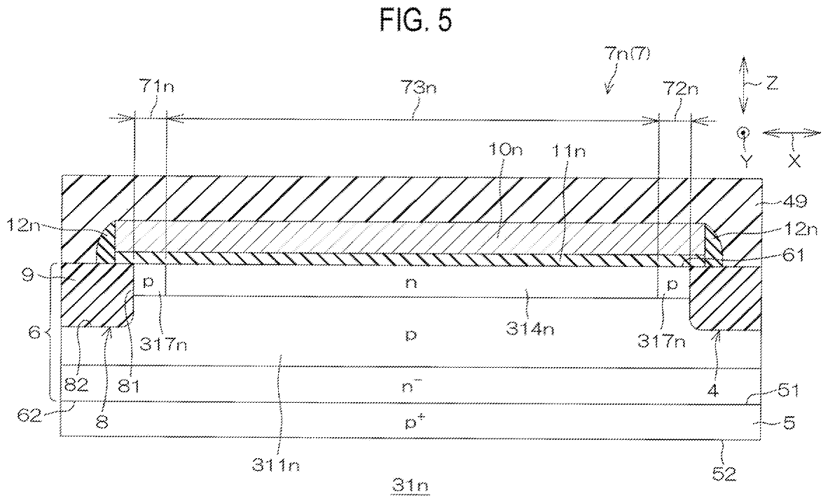

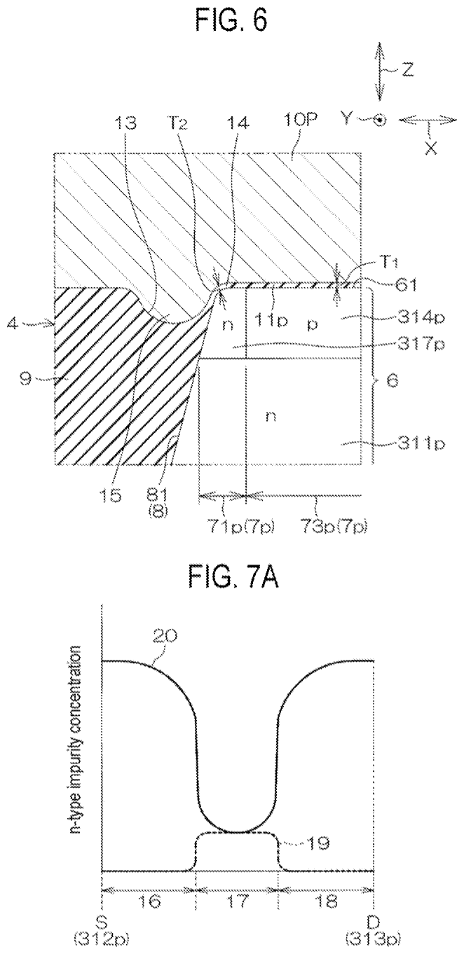

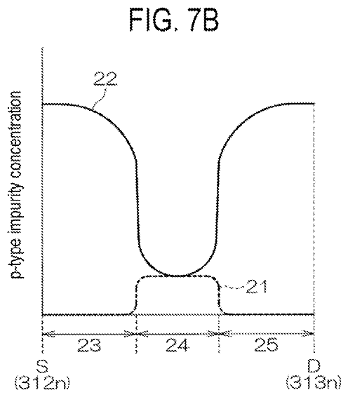

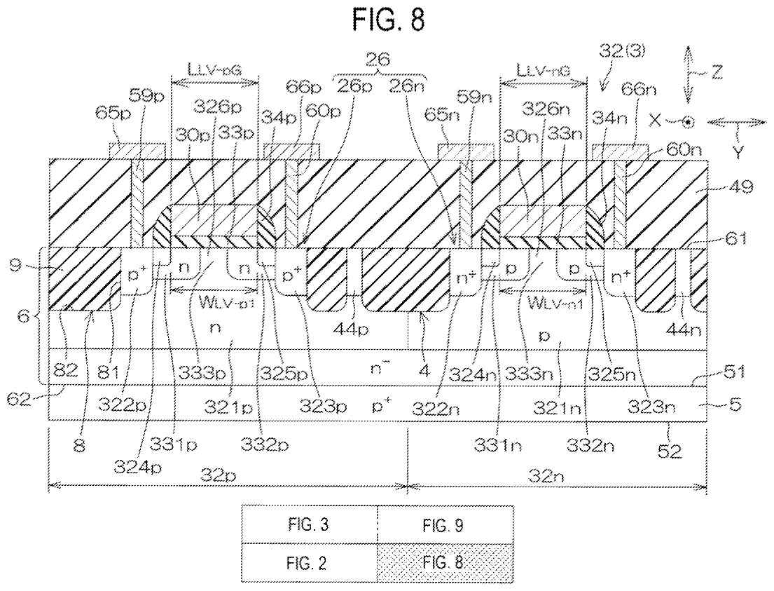

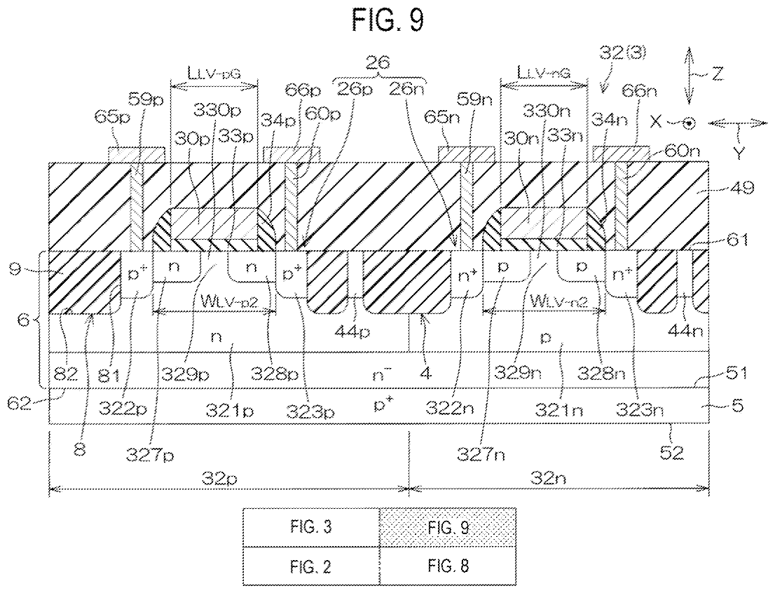

FIGS. 2 and 3 are schematic cross-sectional views of portions surrounded by two-dot chain lines II and III in FIG. 1, respectively. The figure shown in the lower part of each of FIGS. 2 and 3 schematically shows a relative positional relationship in FIG. 1 of the cross sections shown in FIG. 2, FIG. 3, and FIGS. 8 and 9 to be described later. FIGS. 4 and 5 are views showing cross sections taken along line IV-IV and line V-V in FIG. 1, respectively. FIG. 6 is an enlarged view of a portion surrounded by two-dot chain line VI in FIG. 4. FIGS. 7A and 7B are diagrams showing impurity concentration profiles of the medium withstand voltage p-type channel MOS transistor 31p and the medium withstand voltage n-type channel MOS transistor 31n.

Referring to FIGS. 1 to 5, the medium withstand voltage p-type channel MOS transistor 31p and the medium withstand voltage n-type channel MOS transistor 31n are formed on a common semiconductor substrate 5. In this embodiment, the semiconductor substrate 5 may be a p-type silicon substrate. The impurity concentration of the semiconductor substrate 5 may be, for example, 1.0×10¹³ cm⁻³ or more and 1.0×10²⁰ cm⁻³ or less. The semiconductor substrate 5 includes a first main surface 51 and a second main surface 52 on the opposite side of the first main surface 51. The first main surface 51 and the second main surface 52 may be paraphrased as a front surface and a back surface of the semiconductor substrate 5, respectively. The indication of “p⁺” in the semiconductor substrate 5 shown in FIGS. 2 to 5 merely indicates a relative magnitude relationship of an impurity concentration between the semiconductor substrate 5 and the below-described p-type impurity region such as an MV-p-type well 311n or the like for the sake of convenience, and does not define the impurity concentration in a specific range. Hereinafter, the indications of “p⁻”, “p”, “n⁻”, “n”, and “n⁺” shown in FIGS. 2 to 6 are also used with the same meaning.

An epitaxial layer 6 is formed on the semiconductor substrate 5. In this embodiment, the epitaxial layer 6 may be an n-type silicon semiconductor layer. The impurity concentration of the epitaxial layer 6 may be, for example, 1.0×10¹³ cm⁻³ or more and 1.0×10¹⁷ cm⁻³ or less. The epitaxial layer 6 may include a first main surface 61 and a second main surface 62 on the opposite side of the first main surface 61. The first main surface 61 and the second main surface 62 may be paraphrased as a front surface and a back surface of the epitaxial layer 6, respectively. The second main surface 62 of the epitaxial layer 6 may be a surface bonded to the first main surface 51 of the semiconductor substrate 5.

An element isolation portion 4, which partitions a region on the first main surface 61 of the epitaxial layer 6 into a plurality of active regions, is formed in the epitaxial layer 6. Referring to FIG. 1, the element isolation portion 4 partitions the MV-active region 7 for the medium withstand voltage CMOS transistor 31 on the first main surface 61 of the epitaxial layer 6. The MV-active region 7 is further partitioned into an MV-p-side active region 7p for the medium withstand voltage p-type channel MOS transistor 31p and an MV-n-side active region 7n for the medium withstand voltage n-type channel MOS transistor 31n. The MV-p-side active region 7p and the MV-n-side active region 7n are adjacent to each other across the element isolation portion 4 in the second direction Y. Further, the MV-p-side active region 7p and the MV-n-side active region 7n may be formed in a long rectangular shape of the same size along the first direction X in a plan view from the normal direction of the first main surface 61 (hereinafter, simply referred to as “plan view”).

Referring to FIG. 4, the MV-p-side active region 7p may include a first end portion 71p on one side, a second end portion 72p on the opposite side, and a central portion 73p between the first end portion 71p and the second end portion 72p in the first direction X. There may not be a clear boundary between the first end portion 71p and the second end portion 72p on one hand and the central portion 73p on the other hand. For example, a portion falling within a range of 0.1 μm or more and 2.0 μm or less from the boundary between the MV-p-side active region 7p and the element isolation portion 4 toward the inside in the first direction X may be the first end portion 71p and the second end portion 72p, and the other portion may be the central portion 73p.

In this embodiment, the element isolation portion 4 includes a trench 8 formed in the epitaxial layer 6 and an embedded insulating layer 9 embedded in the trench 8. The trench 8 includes a side surface 81 and a bottom surface 82. The side surface 81 of the trench 8 may be a surface orthogonal to the first main surface 61 of the epitaxial layer 6 as shown in FIGS. 2 to 5, or may be a surface inclined with respect to the first main surface 61 of the epitaxial layer 6 as shown in FIG. 6. In the case of FIG. 6, the trench 8 may have a tapered shape whose width becomes smaller from the first main surface 61 toward the bottom surface 82 in the third direction Z in a cross-sectional view. The embedded insulating layer 9 may be made of, for example, silicon oxide (SiO₂), silicon nitride (SiN), or the like. In this embodiment, the embedded insulating layer 9 is made of silicon oxide. Further, the element isolation portion 4 may be referred to as STI (Shallow Trench Isolation) as a general name.

Referring to FIGS. 1 to 4, in the MV-p-side active region 7p, an MV-p-side gate electrode 10p is formed on the first main surface 61 of the epitaxial layer 6. The MV-p-side gate electrode 10p extends across the MV-p-side active region 7p in the first direction X. More specifically, the MV-p-side gate electrode 10p includes both ends on the element isolation portion 4 surrounding the MV-p-side active region 7p, and may be built between the parts of the element isolation portion 4 facing each other across the MV-p-side active region 7p. In this embodiment, the MV-p-side gate electrode 10p is made of, for example, polysilicon, but may be made of a metallic material such as aluminum (Al) or the like. Referring to FIG. 2, the MV-p-side gate length L_{MV-pG}, which is the length of the MV-p-side gate electrode 10p in the second direction Y, may be, for example, 0.3 μm or more and 10.0 μm or less.

An MV-p-side gate insulating film 11p is formed between the MV-p-side gate electrode 10p and the epitaxial layer 6. The MV-p-side gate insulating film 11p may be made of, for example, silicon oxide (SiO₂), silicon nitride (SiN), or the like. In this embodiment, the MV-p-side gate insulating film 11p is made of silicon oxide. The thickness of the MV-p-side gate insulating film 11p may be, for example, 50 Å or more and 250 Å or less.

An MV-p-side sidewall 12p is formed around the MV-p-side gate electrode 10p. The MV-p-side sidewall 12p is continuously formed over the entirety of the periphery of the MV-p-side gate electrode 10p so as to cover the side surface of the MV-p-side gate electrode 10p. The MV-p-side sidewall 12p may be made of, for example, silicon oxide (SiO₂), silicon nitride (SiN), or the like. In this embodiment, the MV-p-side sidewall 12p is made of silicon oxide.

Now, the cross-sectional structure of the MV-p-side gate electrode 10p at the first end portion 71p and the second end portion 72p of the MV-p-side active region 7p will be described in detail with reference to FIG. 6. In FIG. 6, the structure of the first end portion 71p is shown as an example. The structure of the first end portion 71p may be applied to the second end portion 72p as well. A recess 13 is selectively formed in the embedded insulating layer 9 in the vicinity of the first end portion 71p of the MV-p-side active region 7p. The recess 13 is a recess generated due to a cleaning process (light etching with a hydrofluoric acid solution, or the like) which is performed each time before a thermal oxidation step for forming a gate insulating film to be described later, and may be referred to as a divot. As shown by hatching in FIG. 1, the recess 13 may be continuously formed over the entirety of the periphery of the MV-p-side active region 7p so as to surround the MV-p-side active region 7p.

In the portion of the recess 13, a substantial thin film portion 14 is formed in the MV-p-side gate insulating film 11p. For example, the thickness T1 of the MV-p-side gate insulating film 11p at the central portion 73p is 50 Å or more and 250 Å or less, and the thickness T2 of the thin film portion 14 is smaller than the thickness T1 of the central portion 73p. The thin film portion 14 causes a leak and causes a decrease in the withstand voltage of the MV-p-side gate insulating film 11p. The thin film portion 14 partially forms a region having a low threshold value, which results in deterioration of the static characteristics of the medium withstand voltage p-type channel MOS transistor 31p (the threshold value becomes unstable, etc.). Therefore, this embodiment provides a structure that does not cause the deterioration of the static characteristics.

The MV-p-side gate electrode 10p covers the recess 13 of the embedded insulating layer 9, and may include an embedded portion 15 embedded in the recess 13. Referring to FIGS. 2 to 4, an MV-n-type well 311p for the medium withstand voltage p-type channel MOS transistor 31p is formed on the surface layer portion of the epitaxial layer 6. The impurity concentration of the MV-n-type well 311p is higher than the impurity concentration of the epitaxial layer 6, and may be, for example, 1.0×10¹⁷ cm⁻³ or more and 1.0×10¹⁹ cm⁻³ or less. A medium withstand voltage p-type channel MOS transistor 31p is formed in the MV-n-type well 311p.

A pair of p-type source region 312p and p-type drain region 313p is formed at an interval on the surface layer portion of the MV-n-type well 311p. The impurity concentration of the p-type source region 312p and the p-type drain region 313p is higher than the impurity concentration of the MV-n-type well 311p, and may be, for example, 1.0×10¹⁹ cm⁻³ or more and 1.0×10²¹ cm⁻³ or less. Referring to FIG. 1, the p-type source region 312p and the p-type drain region 313p extend parallel to each other along the first direction X. The p-type source region 312p and the p-type drain region 313p may be formed in a rectangular shape of the same size elongated along the first direction X in a plan view. The p-type source region 312p and the p-type drain region 313p continuously extend from the first end portion 71p of the MV-p-side active region 7p to the second end portion 72p via the central portion 73p in the first direction X. Referring to FIGS. 2 and 3, the p-type source region 312p and the p-type drain region 313p are formed in a self-aligned manner with respect to the MV-p-side sidewall 12p.

At the central portion 73p of the MV-p-side active region 7p, a p-type source DDD (Double Diffused Drain) region 314p and a p-type drain DDD (Double Diffused Drain) region 315p, which extend integrally along the second direction Y from the p-type source region 312p and the p-type drain region 313p, respectively, are formed. The impurity concentrations of the p-type source DDD region 314p and the p-type drain DDD region 315p are lower than the impurity concentrations of the p-type source region 312p and the p-type drain region 313p, and may be, for example, 1.0×10¹⁸ cm⁻³ or more and 1.0×10²⁰ cm⁻³ or less. Referring to FIG. 2, the p-type source DDD region 314p and the p-type drain DDD region 315p extend across the boundary between the MV-p-side sidewall 12p and the MV-p-side gate electrode 10p along the second direction Y, and face the MV-p-side gate electrode 10p with the MV-p-side gate insulating film 11p interposed therebetween. Referring to FIG. 4, the p-type source DDD region 314p extends continuously along the first direction X. Although not shown, the p-type drain DDD region 315p also extends continuously along the first direction X.

At the central portion 73p of the MV-p-side active region 7p, the n-type region between the p-type source DDD region 314p and the p-type drain DDD region 315p is an MV-p-side first channel region 316p. The MV-p-side gate electrode 10p faces the MV-p-side first channel region 316p with the MV-p-side gate insulating film 11p interposed therebetween. The MV-p-side first channel region 316p is formed at a part of the MV-n-type well 311p. Referring to FIG. 7A, the concentration profile 19 of the n-type impurity in the MV-p-side first channel region 316p may be substantially constant from the p-type source region 312p to the p-type drain region 313p in the second direction Y. The concentration profile 19 can be measured by, for example, a method such as SMM (Scanning Microwave Microscopy) or SCM (Scanning Capacitance Microscopy).

Since the p-type source region 312p and the p-type source DDD region 314p are all p types and integrated p-type impurity regions, they may be collectively and simply referred to as p-type source regions. Similarly, since the p-type drain region 313p and the p-type drain DDD region 315p are all p types and integrated p-type impurity regions, they may be collectively and simply referred to as p-type drain regions.

Referring to FIGS. 3 and 4, at the first end portion 71p and the second end portion 72p of the MV-p-side active region 7p, an n-type source end region 317p and an n-type drain end region 318p, which extend integrally along the second direction Y from each of the p-type source region 312p and the p-type drain region 313p, are formed. The impurity concentration of the n-type source end region 317p and the n-type drain end region 318p is higher than the impurity concentration of the MV-n-type well 311p, and may be, for example, 1.0×10¹⁸ cm⁻³ or more and 1.0×10²⁰ cm⁻³ or less. Referring to FIG. 3, the n-type source end region 317p and the n-type drain end region 318p extend across the boundary between the MV-p-side sidewall 12p and the MV-p-side gate electrode 10p along the second direction Y, and face the MV-p-side gate electrode 10p with the MV-p-side gate insulating film 11p interposed therebetween.

In the second direction Y, the region sandwiched between the n-type source end region 31′7p and the n-type drain end region 318p is the n-type end low concentration region 319p formed at a part of the MV-n-type well 311p. At the first end portion 71p and the second end portion 72p of the MV-p-side active region 7p, the n-type region between the p-type source region 312p and the p-type drain region 313p is an MV-p-side second channel region 320p. That is, the n-type source end region 317p, the n-type drain end region 318p, and the n-type end low concentration region 319p form the MV-p-side second channel region 320p. The MV-p-side gate electrode 10p (mainly the thin film portion 14) faces the MV-p-side second channel region 320p with the MV-p-side gate insulating film 11p interposed therebetween.

Referring to FIG. 7A, the concentration profile 20 of the n-type impurity in the MV-p-side second channel region 320p includes an MV-n-type first section 16, an MV-n-type second section 17 changing within an impurity concentration lower than the impurity concentration in the MV-n-type first section 16, and an MV-n-type third section 18 changing within an impurity concentration higher than the impurity concentration in the MV-n-type second section 17, which are arranged sequentially from the p-type source region 312p toward the p-type drain region 313p in the second direction Y. For example, the MV-n-type first section 16 may correspond to the n-type source end region 317p, the MV-n-type second section 17 may correspond to the n-type end low concentration region 319p, and the MV-n-type third section 18 may correspond to the n-type drain end region 318p. The concentration profile 20 can be measured by, for example, a method such as SMM (Scanning Microwave Microscopy) or SCM (Scanning Capacitance Microscopy).

Referring to FIGS. 2 and 3, if the first width W_{MV-p1} of the MV-p-side first channel region 316p in the second direction Y and the second width W_{MV-p2} of the MV-p-side second channel region 320p in the second direction Y are compared with each other, the second width W_{MV-p2} is relatively large. For example, the first width W_{MV-p1} may be 0.2 μm or more and 10.0 μm or less, and the second width W_{MV-p2} may be 0.3 μm or more and 10.0 μm or less.

Further, an MV-n-type back gate region 43p is formed on the surface layer portion of the MV-n-type well 311p. The MV-n-type back gate region 43p is electrically connected to the MV-n-type well 311p. Referring to FIG. 5, the MV-n-side active region 7n may include a first end portion 71n on one side, a second end portion 72n on the opposite side of the first end portion 71n, and a central portion 73n between the first end portion 71n and the second end portion 72n, which are arranged in the first direction X. There may not be a clear boundary between the first end portion 71n and the second end portion 72n on one hand and the central portion 73n on the other hand. For example, the range of 0.1 μm or more and 2.0 μm or less from the boundary between the MV-n-side active region 7n and the element isolation portion 4 toward the inside in the first direction X may be the first end portion 71n and the second end portion 72n, and the remaining portion may be the central portion 73n.

Referring to FIGS. 1 to 3 and FIG. 5, in the MV-n-side active region 7n, an MV-n-side gate electrode 10n is formed on the first main surface 61 of the epitaxial layer 6. The MV-n-side gate electrode 10n extends across the MV-n-side active region 7n in the first direction X. More specifically, the MV-n-side gate electrode 10n may include both ends on the element isolation portion 4 surrounding the MV-n-side active region 7n, and may be provided between the parts of the element isolation portion 4 facing each other across the MV-n-side active region 7n. In this embodiment, the MV-n-side gate electrode 10n is made of, for example, polysilicon, and may also be made of a metallic material such as aluminum (Al) or the like. Referring to FIG. 2, the MV-n-side gate length L_{MV-nG}, which is the length of the MV-n-side gate electrode 10n in the second direction Y, may be, for example, 0.3 μm or more and 10.0 μm or less.

An MV-n-side gate insulating film 11n is formed between the MV-n-side gate electrode 10n and the epitaxial layer 6. The MV-n-side gate insulating film 11n may be made of, for example, silicon oxide (SiO₂), silicon nitride (SiN), or the like. In this embodiment, the MV-n-side gate insulating film 11n is made of silicon oxide. The thickness of the MV-n-side gate insulating film 11n may be, for example, 50 Å or more and 250 Å or less.

An MV-n-side sidewall 12n is formed around the MV-n-side gate electrode 10n. The MV-n-side sidewall 12n is continuously formed over the entirety of the periphery of the MV-n-side gate electrode 10n so as to cover the side surface of the MV-n-side gate electrode 10n. The MV-n-side sidewall 12n may be made of, for example, silicon oxide (SiO₂), silicon nitride (SiN), or the like. In this embodiment, the MV-n-side sidewall 12n is made of silicon oxide.

In the vicinity of the first end portion 71n and the second end portion 72n of the MV-n-side active region 7n, a recess 13 surrounding the MV-n-side active region 7n may be formed like the recess 13 shown in FIG. 6 (see the hatched portion in FIG. 1). Referring to FIGS. 2, 3 and 5, an MV-p-type well 311n for the medium withstand voltage n-type channel MOS transistor 31n is formed on the surface layer portion of the epitaxial layer 6. The impurity concentration of the MV-p-type well 311n is higher than the impurity concentration of the epitaxial layer 6, and may be, for example, 1.0×10¹⁷ cm⁻³ or more and 1.0×10¹⁹ cm⁻³ or less. The medium withstand voltage n-type channel MOS transistor 31n is formed in the MV-p-type well 311n.

A pair of n-type source region 312n and n-type drain region 313n is formed at an interval on the surface layer portion of the MV-p-type well 311n. The impurity concentration of the n-type source region 312n and the n-type drain region 313n is higher than the impurity concentration of the MV-p-type well 311n, and may be, for example, 1.0×10¹⁹ cm⁻³ or more and 1.0×10²¹ cm⁻³ or less. Referring to FIG. 1, the n-type source region 312n and the n-type drain region 313n extend parallel to each other along the first direction X. The n-type source region 312n and the n-type drain region 313n may be formed in a rectangular shape of the same size elongated along the first direction X in a plan view. The n-type source region 312n and the n-type drain region 313n extend continuously from the first end portion 71n of the MV-n-side active region 7n to the second end portion 72n via the central portion 73n in the first direction X. Referring to FIGS. 2 and 3, the n-type source region 312n and the n-type drain region 313n are formed in a self-aligned manner with respect to the MV-n-side sidewall 12n.

At the central portion 73n of the MV-n-side active region 7n, an n-type source DDD (Double Diffused Drain) region 314n and an n-type drain DDD (Double Diffused Drain) region 315n, which extend integrally along the second direction Y from each of the n-type source region 312n and the n-type drain region 313n, are formed. The impurity concentrations of the n-type source DDD region 314n and the n-type drain DDD region 315n are lower than the impurity concentrations of the n-type source region 312n and the n-type drain region 313n, and may be, for example, 1.0×10¹⁸ cm⁻³ or more and 1.0×10²⁰ cm⁻³ or less. Referring to FIG. 5, the n-type source DDD region 314n extends continuously along the first direction X. Although not shown, the n-type drain DDD region 315n also extends continuously along the first direction X. Referring to FIG. 2, the n-type source DDD region 314n and the n-type drain DDD region 315n extend across the boundary between the MV-n-side sidewall 12n and the MV-n-side gate electrode 10n along the second direction Y, and face the MV-n-side gate electrode 10n with the MV-n-side gate insulating film 11n interposed therebetween.

At the central portion 73n of the MV-n-side active region 7n, the p-type region between the n-type source DDD region 314n and the n-type drain DDD region 315n is an MV-n-side first channel region 316n. The MV-n-side gate electrode 10n faces the MV-n-side first channel region 316n with the MV-n-side gate insulating film 11n interposed therebetween. The MV-n-side first channel region 316n is formed at a part of the MV-p-type well 311n. Referring to FIG. 7B, the concentration profile 21 of the p-type impurity in the MV-n-side first channel region 316n may be substantially constant from the n-type source region 312n to the n-type drain region 313n in the second direction Y. The concentration profile 21 can be measured by, for example, a method such as SMM (Scanning Microwave Microscopy) or SCM (Scanning Capacitance Microscopy).

Since the n-type source region 312n and the n-type source DDD region 314n are all n types and integrated n-type impurity regions, they may be collectively and simply referred to as n-type source regions. Similarly, since the n-type drain region 313n and the n-type drain DDD region 315n are all n types and integrated n-type impurity regions, they may be collectively and simply referred to as n-type drain regions.

Referring to FIGS. 3 and 5, at the first end portion 71n and the second end portion 72n of the MV-n-side active region 7n, a p-type source end region 317n and a p-type drain end region 318n, which extend integrally along the second direction Y from each of the n-type source region 312n and the n-type drain region 313n, respectively, are formed. The impurity concentration of the p-type source end region 317n and the p-type drain end region 318n is higher than the impurity concentration of the MV-p-type well 311n, and may be, for example, 1.0×10¹⁸ cm⁻³ or more and 1.0×10²⁰ cm⁻³ or less. Referring to FIG. 3, the p-type source end region 317n and the p-type drain end region 318n extend across the boundary between the MV-n-side sidewall 12n and the MV-n-side gate electrode 10n along the second direction Y, and face the MV-n-side gate electrode 10n with the MV-n-side gate insulating film 11n interposed therebetween.

In the second direction Y, the region sandwiched between the p-type source end region 317n and the p-type drain end region 318n is a p-type end low concentration region 319n formed at a part of the MV-p-type well 311n. At the first end portion 71n and the second end portion 72n of the MV-n-side active region 7n, the p-type region between the n-type source region 312p and the n-type drain region 313n is an MV-n-side second channel region 320n. That is, the p-type source end region 317n, the p-type drain end region 318n, and the p-type end low concentration region 319n form the MV-n-side second channel region 320n. The MV-n-side gate electrode 10n (mainly the thin film portion 14) faces the MV-n-side second channel region 320n with the MV-n-side gate insulating film 11n interposed therebetween.

Referring to FIG. 7B, the concentration profile 22 of the n-type impurity in the MV-n-side second channel region 320n includes an MV-p-type first section 23, an MV-p-type second section 24 changing within an impurity concentration lower than the impurity concentration in the MV-p-type first section 23, and an MV-p-type third section 25 changing within an impurity concentration higher than the impurity concentration in the MV-p-type second section 24, which are arranged sequentially from the n-type source region 312n toward the n-type drain region 313n in the second direction Y. For example, the MV-p-type first section 23 may correspond to the p-type source end region 317n, the MV-p-type second section 24 may correspond to the p-type end low concentration region 319n, and the MV-p-type third section 25 may correspond to the p-type drain end region 318n. The concentration profile 22 can be measured by, for example, a method such as SMM (Scanning Microwave Microscopy) or SCM (Scanning Capacitance Microscopy).

Referring to FIGS. 2 and 3, if the first width W_{MV-n1} of the MV-n-side first channel region 316n in the second direction Y and the second width W_{MV-n2} of the MV-n-side second channel region 320n in the second direction Y are compared with each other, the second width W_{MV-n2} is relatively large. For example, the first width W_{MV-n1} may be 0.2 μm or more and 10.0 μm or less, and the second width W_{MV-n2} may be 0.3 μm or more and 10.0 μm or less.

Further, an MV-p-type back gate region 43n is formed on the surface layer portion of the MV-p-type well 311n. The MV-p-type back gate region 43n is electrically connected to the MV-p-type well 311n.

### [Structure of Low Withstand Voltage CMOS Transistor 32]

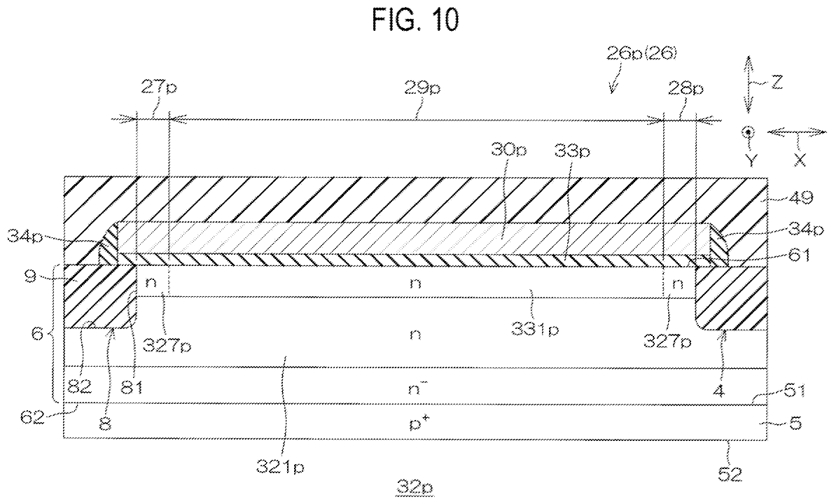

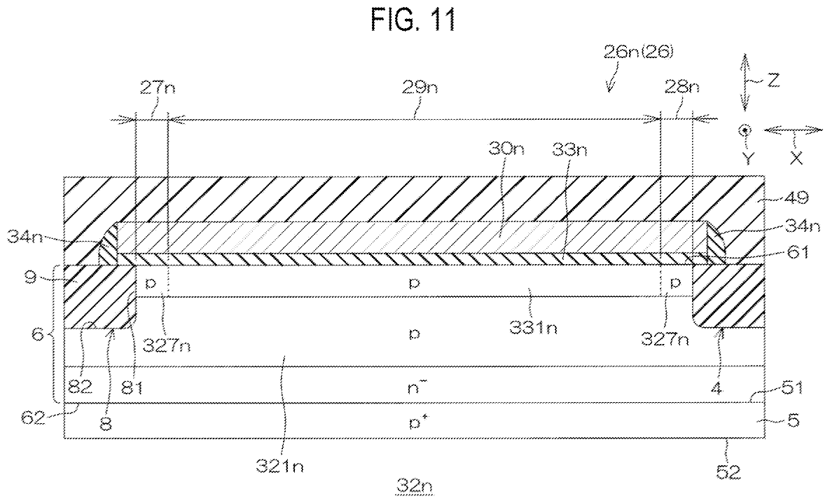

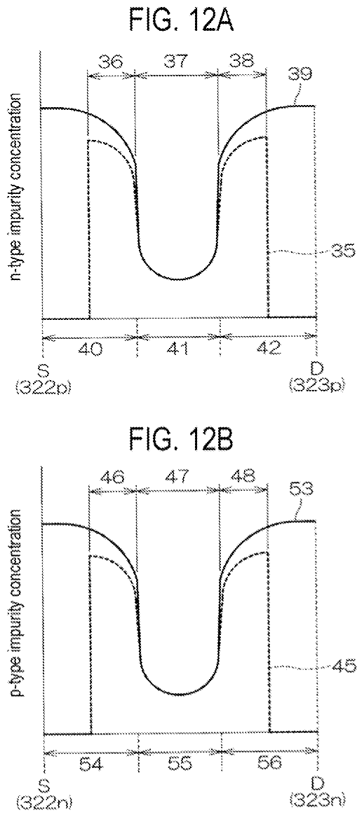

FIGS. 8 and 9 are schematic cross-sectional views of the portions surrounded by two-dot chain lines VIII and IX in FIG. 1, respectively. The figure shown in the lower part of each of FIGS. 8 and 9 schematically shows the relative positional relationship in FIG. 1 of the cross sections shown in FIGS. 2, 3, 8, and 9. FIGS. 10 and 11 are views showing the cross sections taken along line X-X and line XI-XI in FIG. 1, respectively. FIGS. 12A and 12B are diagrams showing impurity concentration profiles of the low withstand voltage p-type channel MOS transistor 32p and the low withstand voltage n-type channel MOS transistor 32n.

Referring to FIG. 1, the element isolation portion 4 partitions an LV-active region 26 for the low withstand voltage CMOS transistor 32 on the first main surface 61 of the epitaxial layer 6. The LV-active region 26 is further partitioned into an LV-p-side active region 26p for the low withstand voltage p-type channel MOS transistor 32p and an LV-n-side active region 26n for the low withstand voltage n-type channel MOS transistor 32n. The LV-p-side active region 26p and the LV-n-side active region 26n are adjacent to each other across the element isolation portion 4 in the second direction Y. Further, the LV-p-side active region 26p and the LV-n-side active region 26n may be formed in a rectangular shape of the same size elongated along the first direction X in a plan view.

Referring to FIG. 10, the LV-p-side active region 26p may include a first end portion 27p on one side, a second end portion 28p on the opposite side of the first end portion 27p, and a central portion 29p between the first end portion 27p and the second end portion 28p in the first direction X. There may not be a clear boundary between the first end portion 27p and the second end portion 28p on one hand and the central portion 29p on the other hand. For example, a portion falling within a range of 0.1 μm or more and 2.0 μm or less from the boundary between the LV-p-side active region 26p and the element isolation portion 4 toward the inside in the first direction X may be the first end portion 27p and the second end portion 28p, and the remaining portion may be the central portion 29p.

Referring to FIGS. 1 and 8 to 10, in the LV-p-side active region 26p, the LV-p-side gate electrode 30p is formed on the first main surface 61 of the epitaxial layer 6. The LV-p-side gate electrode 30p extends across the LV-p-side active region 26p in the first direction X. More specifically, the LV-p-side gate electrode 30p may include both ends on the element isolation portion 4 surrounding the LV-p-side active region 26p, and may be installed between the parts of the element isolation portion 4 facing each other across the LV-p-side active region 26p. In this embodiment, the LV-p-side gate electrode 30p is made of, for example, polysilicon, and may also be made of a metallic material such as aluminum (Al) or the like. Referring to FIG. 8, the LV-p-side gate length L_{LV_pG}, which is the length of the LV-p-side gate electrode 30p in the second direction Y, may be, for example, 0.05 μm or more and 10.0 μm or less.

An LV-p-side gate insulating film 33p is formed between the LV-p-side gate electrode 30p and the epitaxial layer 6. The LV-p-side gate insulating film 33p may be made of, for example, silicon oxide (SiO₂), silicon nitride (SiN), or the like. In this embodiment, the LV-p-side gate insulating film 33p is made of silicon oxide. The thickness of the LV-p-side gate insulating film 33p may be, for example, 10 Å or more and 50 Å or less.

An LV-p-side sidewall 34p is formed around the LV-p-side gate electrode 30p. The LV-p-side sidewall 34p is continuously formed over the entirety of the periphery of the LV-p-side gate electrode 30p so as to cover the side surface of the LV-p-side gate electrode 30p. The LV-p-side sidewall 34p may be made of, for example, silicon oxide (SiO₂), silicon nitride (SiN), or the like. In this embodiment, the LV-p-side sidewall 34p is made of silicon oxide.

In the vicinity of the first end portion 71p and the second end portion 72p of the LV-p-side active region 26p, a recess 13 surrounding the LV-p-side active region 26p may be formed like the recess 13 shown in FIG. 6 (see the hatched portion in FIG. 1). Referring to FIGS. 8 to 10, an LV-n-type well 321p for the low withstand voltage p-type channel MOS transistor 32p is formed on the surface layer portion of the epitaxial layer 6. The impurity concentration of the LV-n-type well 321p is higher than the impurity concentration of the epitaxial layer 6, and may be, for example, 1.0×10¹⁷ cm⁻³ or more and 1.0×10¹⁹ cm⁻³ or less. The low withstand voltage p-type channel MOS transistor 32p is formed in the LV-n-type well 321p.

A pair of p-type source region 322p and p-type drain region 323p is formed at an interval on the surface layer portion of the LV-n-type well 321p. The impurity concentration of the p-type source region 322p and the p-type drain region 323p is higher than the impurity concentration of the LV-n-type well 321p, and may be, for example, 1.0×10¹⁹ cm⁻³ or more and 1.0×10²¹ cm⁻³ or less. Referring to FIG. 1, the p-type source region 322p and the p-type drain region 323p extend parallel to each other along the first direction X. The p-type source region 322p and the p-type drain region 323p may be formed in a rectangular shape of the same size elongated along the first direction X in a plan view. The p-type source region 322p and the p-type drain region 323p extend continuously from the first end portion 27p of the LV-p-side active region 26p to the second end portion 28p via the central portion 29p in the first direction X. Referring to FIGS. 8 and 9, the p-type source region 322p and the p-type drain region 323p are formed in a self-aligned manner with respect to the LV-p-side sidewall 34p.

At the central portion 29p of the LV-p-side active region 26p, a p-type source extension region 324p and a p-type drain extension region 325p, which extend integrally along the second direction Y from each of the p-type source region 322p and the p-type drain region 323p, are formed. The impurity concentrations of the p-type source extension region 324p and the p-type drain extension region 325p are lower than the impurity concentrations of the p-type source region 322p and the p-type drain region 323p, and may be, for example, 1.0×10¹⁸ cm⁻³ or more and 1.0×10²¹ cm⁻³ or less. Referring to FIG. 8, the p-type source extension region 324p and the p-type drain extension region 325p are formed in a self-aligned manner with respect to the LV-p-side gate electrode 30p.

At the central portion 29p of the LV-p-side active region 26p, an n-type source pocket implantation region 331p and an n-type drain pocket implantation region 332p, which extend integrally along the second direction Y from each of the p-type source region 322p and the p-type drain region 323p, are additionally formed. The impurity concentrations of the n-type source pocket implantation region 331p and the n-type drain pocket implantation region 332p are higher than the impurity concentrations of the LV-n-type well 321p, and may be, for example, 1.0×10¹⁸ cm⁻³ or more and 1.0×10²⁰ cm⁻³ or less. Referring to FIG. 8, the n-type source pocket implantation region 331p and the n-type drain pocket implantation region 332p extend across the boundary between the LV-p-side sidewall 34p and the LV-p-side gate electrode 30p along the second direction Y, and face the LV-p-side gate electrode 30p with the LV-p-side gate insulating film 33p interposed therebetween. Further, the n-type source pocket implantation region 331p and the n-type drain pocket implantation region 332p cover the bottom portions and the side portions of the p-type source extension region 324p and the p-type drain extension region 325p, respectively. Referring to FIG. 10, the n-type source pocket implantation region 331p extends continuously along the first direction X. Although not shown, the n-type drain pocket implantation region 332p also extends continuously along the first direction X.

In the second direction Y, the region sandwiched between the n-type source pocket implantation region 331p and the n-type drain pocket implantation region 332p is an n-type central low concentration region 333p formed at a part of the LV-n-type well 321p. At the central portion 29p of the LV-p-side active region 26p, the n-type region between the pair of p-type source extension region 324p and p-type drain extension region 325p is an LV-p-side first channel region 326p. That is, the n-type source pocket implantation region 331p, the n-type drain pocket implantation region 332p, and the n-type central low concentration region 333p form the LV-p-side first channel region 326p. The LV-p-side gate electrode 30p faces the LV-p-side first channel region 326p with the LV-p-side gate insulating film 33p interposed therebetween.

Referring to FIG. 12A, the concentration profile 35 of the n-type impurity of the LV-p-side first channel region 326p includes an LV-n-type first section 36, an LV-n-type second section 37 changing within an impurity concentration lower than the impurity concentration in the LV-n-type first section 36, and an LV-n-type third section 38 changing within an impurity concentration higher than the impurity concentration in the LV-n-type second section 37, which are arranged sequentially from the p-type source region 322p toward the p-type drain region 323p in the second direction Y. For example, the LV-n-type first section 36 may correspond to the n-type source pocket implantation region 331p, the LV-n-type second section 37 may correspond to the n-type central low concentration region 333p, and the LV-n-type third section 38 may correspond to the n-type drain pocket implantation region 332p. The concentration profile 35 can be measured by, for example, a method such as SMM (Scanning Microwave Microscopy) or SCM (Scanning Capacitance Microscopy).

Since the p-type source region 322p and the p-type source extension region 324p are all p types and integrated p-type impurity regions, they may be collectively and simply referred to as p-type source regions. Similarly, since the p-type drain region 323p and the p-type drain extension region 325p are all p types and integrated p-type impurity regions, they may be collectively and simply referred to as p-type drain regions.

Further, the p-type source extension region 324p and the n-type source pocket implantation region 331p, which extend from the p-type source region 322p to below the LV-p-side gate electrode 30p, may be collectively referred to as p-side source LDD (Lightly Doped Drain) regions. Similarly, the p-type drain extension region 325p and the n-type drain pocket implantation region 332p, which extend from the p-type drain region 323p to below the LV-p-side gate electrode 30p, may be collectively referred to as p-side drain LDD (Lightly Doped Drain) regions.

Referring to FIGS. 9 and 10, at the first end portion 27p and the second end portion 28p of the LV-p-side active region 26p, an n-type source end region 327p and an n-type drain end region 328p, which extend integrally along the second direction Y from each of the p-type source region 322p and the p-type drain region 323p, respectively, are formed. The impurity concentrations of the n-type source end region 327p and the n-type drain end region 328p, which are higher than the impurity concentrations of the LV-n-type well 321p, the n-type source pocket implantation region 331p and the n-type drain pocket implantation region 332p, may be, for example, 1.0×10¹⁸ cm⁻³ or more and 1.0×10²⁰ cm⁻³ or less. Referring to FIG. 9, the n-type source end region 327p and the n-type drain end region 328p extend across the boundary between the LV-p-side sidewall 34p and the LV-p-side gate electrode 30p along the second direction Y, and face the LV-p-side gate electrode 30p with the LV-p-side gate insulating film 33p interposed therebetween.

In the second direction Y, the region sandwiched between the n-type source end region 32′7p and the n-type drain end region 328p is an n-type end low concentration region 329p formed at a part of the LV-n-type well 321p. At the first end portion 27p and the second end portion 28p of the LV-p-side active region 26p, the n-type region between the p-type source region 312p and the p-type drain region 323p is an LV-p-side second channel region 330p. That is, the n-type source end region 327p, the n-type drain end region 328p, and the n-type end low concentration region 329p form the LV-p-side second channel region 330p. The LV-p-side gate electrode 30p faces the LV-p-side second channel region 330p with the LV-p-side gate insulating film 33p interposed therebetween.

Referring to FIG. 12A, the concentration profile 39 of the n-type impurity in the LV-p-side second channel region 330p includes an LV-n-type first section 40, an LV-n-type second section 41 changing within an impurity concentration lower than the impurity concentration in the LV-n-type first section 40, and an LV-n-type third section 42 changing within an impurity concentration higher than the impurity concentration in the LV-n-type second section 41, which are arranged sequentially from the p-type source region 322p toward the p-type drain region 323p in the second direction Y. For example, the LV-n-type first section 40 may correspond to the n-type source end region 327p, the LV-n-type second section 41 may correspond to the n-type end low concentration region 329p, and the LV-n-type third section 42 may correspond to the n-type drain end region 328p. The concentration profile 39 can be measured by, for example, a method such as SMM (Scanning Microwave Microscopy) or SCM (Scanning Capacitance Microscopy).

Referring to FIGS. 8 and 9, if the first width W_{LV-p1} of the LV-p-side first channel region 326p in the second direction Y and the second width W_{LV-p2} of the LV-p-side second channel region 330p in the second direction Y are compared with each other, the second width W_{LV-p2} is relatively large. For example, the first width W_{LV-p1} may be 0.05 μm or more and 10.0 μm or less, and the second width W_{LV-p2} may be 0.1 μm or more and 10.0 μm or less.

Further, an LV-n-type back gate region 44p is formed on the surface layer portion of the LV-n-type well 321p. The LV-n-type back gate region 44p is electrically connected to the LV-n-type well 321p. Referring to FIG. 11, the LV-n-side active region 26n may include a first end portion 27n on one side, a second end portion 28n on the opposite side of the first end portion 27n, and a central portion 29n between the first end portion 27n and the second end portion 28n, which are arranged in the first direction X. There may not be a clear boundary between the first end portion 27n and the second end portion 28n on one hand and the central portion 29n on the other hand. For example, a portion falling within a range of 0.1 μm or more and 2.0 μm or less from the boundary between the LV-n-side active region 26n and the element isolation portion 4 toward the inside in the first direction X may be the first end portion 27n and the second end portion 28n, and the remaining portion may be the central portion 29n.

Referring to FIGS. 1, 8, 9 and 11, in the LV-n-side active region 26n, an LV-n-side gate electrode 30n is formed on the first main surface 61 of the epitaxial layer 6. The LV-n-side gate electrode 30n extends across the LV-n-side active region 26n in the first direction X. More specifically, the LV-n-side gate electrode 30n includes both ends on the element isolation portion 4 surrounding the LV-n-side active region 26n, and may be provided between the parts of the element isolation portion 4 facing each other across the LV-n-side active region 26n. In this embodiment, the LV-n-side gate electrode 30n is made of, for example, polysilicon, and may also be made of a metallic material such as aluminum (Al) or the like. Referring to FIG. 8, the LV-n-side gate length L_{LV-nG}, which is the length of the LV-n-side gate electrode 30n in the second direction Y, may be, for example, 0.05 μm or more and 10.0 μm or less.

An LV-n-side gate insulating film 33n is formed between the LV-n-side gate electrode 30n and the epitaxial layer 6. The LV-n-side gate insulating film 33n may be made of, for example, silicon oxide (SiO₂), silicon nitride (SiN), or the like. In this embodiment, the LV-n-side gate insulating film 33n is made of silicon oxide. The thickness of the LV-n-side gate insulating film 33n may be, for example, 10 Å or more and 50 Å or less.

An LV-n-side sidewall 34n is formed around the LV-n-side gate electrode 30n. The LV-n-side sidewall 34n is continuously formed over the entirety of the periphery of the LV-n-side gate electrode 30n so as to cover the side surface of the LV-n-side gate electrode 30n. The LV-n-side sidewall 34n may be made of, for example, silicon oxide (SiO₂), silicon nitride (SiN), or the like. In this embodiment, the LV-n-side sidewall 34n is made of silicon oxide.

In the vicinity of the first end portion 27n and the second end portion 28n of the LV-n-side active region 26n, a recess 13 surrounding the LV-n-side active region 26n may be formed like the recess 13 shown in FIG. 6 (see the hatched portion in FIG. 1). Referring to FIGS. 8, 9, and 11, an LV-p-type well 321n for the low withstand voltage n-type channel MOS transistor 32n is formed on the surface layer portion of the epitaxial layer 6. The impurity concentration of the LV-p-type well 321n is higher than the impurity concentration of the epitaxial layer 6, and may be, for example, 1.0×10¹⁷ cm⁻³ or more and 1.0×10¹⁹ cm⁻³ or less. The low withstand voltage n-type channel MOS transistor 32n is formed in the LV-p-type well 321n.

A pair of n-type source region 322n and n-type drain region 323n is formed at an interval on the surface layer portion of the LV-p-type well 321n. The impurity concentration of the n-type source region 322n and the n-type drain region 323n is higher than the impurity concentration of the LV-p-type well 321n, and may be, for example, 1.0×10¹⁹ cm⁻³ or more and 1.0×10²¹ cm⁻³ or less. Referring to FIG. 1, the n-type source region 322n and the n-type drain region 323n extend parallel to each other along the first direction X. The n-type source region 322n and the n-type drain region 323n may be formed in a rectangular shape of the same size elongated along the first direction X in a plan view. The n-type source region 322n and the n-type drain region 323n continuously extend from the first end portion 27n of the LV-n-side active region 26n to the second end portion 28n via the central portion 29n in the first direction X. Referring to FIGS. 8 and 9, the n-type source region 322n and the n-type drain region 323n are formed in a self-aligned manner with respect to the LV-n-side sidewall 34n.

At the central portion 29n of the LV-n-side active region 26n, an n-type source LDD (Lightly Doped Drain) region 324n and an n-type drain LDD (Lightly Doped Drain) region 325n, which extend integrally along the second direction Y from each of the n-type source region 322n and the n-type drain region 323n, are formed. The impurity concentrations of the n-type source extension region 324n and the n-type drain extension region 325n are lower than the impurity concentration of the n-type source region 322n and the n-type drain region 323n, and may be, for example, 1.0×10¹⁸ cm⁻³ or more and 1.0×10²¹ cm⁻³ or less. Referring to FIG. 8, the n-type source extension region 324n and the n-type drain extension region 325n are formed in a self-aligned manner with respect to the LV-n-side gate electrode 30n.

At the central portion 29n of the LV-n-side active region 26n, a p-type source pocket implantation region 331n and a p-type drain pocket implantation region 332n, which extend integrally along the second direction Y from each of the n-type source region 322n and the n-type drain region 323n, are additionally formed. The impurity concentrations of the p-type source pocket implantation region 331n and the p-type drain pocket implantation region 332n are higher than the impurity concentration of the LV-p-type well 321n, and may be, for example, 1.0×10¹⁸ cm⁻³ or more and 1.0×10²⁰ cm⁻³ or less. Referring to FIG. 8, the p-type source pocket implantation region 331n and the p-type drain pocket implantation region 332n extend across the boundary between the LV-n-side sidewall 34n and the LV-n-side gate electrode 30n along the second direction Y, and face the LV-n-side gate electrode 30n with the LV-n-side gate insulating film 33n interposed therebetween. Further, the p-type source pocket implantation region 331n and the p-type drain pocket implantation region 332n cover the bottom portions and the side portions of the n-type source extension region 324n and the n-type drain extension region 325n, respectively. Referring to FIG. 11, the p-type source pocket implantation region 331n extends continuously along the first direction X. Although not shown, the p-type drain pocket implantation region 332n also extends continuously along the first direction X.

In the second direction Y, the region sandwiched between the p-type source pocket implantation region 331n and the p-type drain pocket implantation region 332n is a p-type central low concentration region 333n formed at a part of the LV-p-type well 321n. At the central portion 29n of the LV-n-side active region 26n, the p-type region between the pair of n-type source extension region 324n and n-type drain extension region 325n is an LV-n-side first channel region 326n. That is, the p-type source pocket implantation region 331n, the p-type drain pocket implantation region 332n, and the p-type central low concentration region 333n form the LV-n-side first channel region 326n. The LV-n-side gate electrode 30n faces the LV-n-side first channel region 326n with the LV-n-side gate insulating film 33n interposed therebetween.

Referring to FIG. 12B, the concentration profile 45 of the p-type impurity of the LV-n-side first channel region 326n includes an LV-p-type first section 46, an LV-p-type second section 47 changing within an impurity concentration lower than the impurity concentration in the LV-p-type first section 46, and an LV-p-type third section 48 changing within an impurity concentration higher than the impurity concentration in the LV-p-type second section 47, which are arranged sequentially from the n-type source region 322p toward the n-type drain region 323n in the second direction Y. For example, the LV-p-type first section 46 may correspond to the p-type source pocket implantation region 331n, the LV-p-type second section 47 may correspond to the p-type central low concentration region 333n, and the LV-p-type third section 48 may correspond to the p-type drain pocket implantation region 332n. The concentration profile 45 can be measured by, for example, a method such as SMM (Scanning Microwave Microscopy) or SCM (Scanning Capacitance Microscopy).

Since the n-type source region 322n and the n-type source extension region 324n are all n types and integrated n-type impurity regions, they may be collectively and simply referred to as n-type source regions. Similarly, since the n-type drain region 323n and the n-type drain extension region 325n are all n types and are integrated n-type impurity regions, they may be collectively and simply referred to as n-type drain regions.

Further, the n-type source extension region 324n and the p-type source pocket implantation region 331n, which extend from the n-type source region 322n to below the LV-n-side gate electrode 30n, may be collectively referred to as n-side source LDD (Lightly Doped Drain) regions. Similarly, the n-type drain extension region 325n and the p-type drain pocket implantation region 332n, which extend from the n-type drain region 323n to below the LV-p-side gate electrode 30n, may be collectively referred to as n-side drain LDD (Lightly Doped Drain) regions.

Referring to FIGS. 9 and 11, at the first end portion 27n and the second end portion 28n of the LV-n-side active region 26n, a p-type source end region 327n and a p-type drain end region 328n, which extend integrally along the second direction Y from each of the n-type source region 322n and the n-type drain region 323n, respectively, are formed. The impurity concentrations of the p-type source end region 327n and the p-type drain end region 328n are higher than the impurity concentrations of the LV-p-type well 321n, the p-type source pocket implantation region 331n and the p-type drain pocket implantation region 332n, and may be, for example, 1.0×10¹⁸ cm⁻³ or more and 1.0×10²⁰ cm⁻³ or less. Referring to FIG. 9, the p-type source end region 327n and the p-type drain end region 328n extend across the boundary between the LV-n-side sidewall 34n and the LV-n-side gate electrode 30n along the second direction Y, and face the LV-n-side gate electrode 30n with the LV-n-side gate insulating film 33n interposed therebetween.

In the second direction Y, the region sandwiched between the p-type source end region 327n and the p-type drain end region 328n is a p-type end low concentration region 329n formed at a part of the LV-p-type well 321n. At the first end portion 27n and the second end portion 28n of the LV-n-side active region 26n, the p-type region between the n-type source region 312n and the n-type drain region 323n is an LV-n-side second channel region 330n. That is, the p-type source end region 327n, the p-type drain end region 328n, and the p-type end low concentration region 329n form the LV-n-side second channel region 330n. The LV-n-side gate electrode 30n faces the LV-n-side second channel region 330n with the LV-n-side gate insulating film 33n interposed therebetween.

Referring to FIG. 12B, the concentration profile 53 of the n-type impurity in the LV-n-side second channel region 330n includes an LV-p-type first section 54, an LV-p-type second section 55 changing within an impurity concentration lower than the impurity concentration in the LV-p-type first section 54, and an LV-p-type third section 56 changing within an impurity concentration higher than the impurity concentration in the LV-p-type second section 55, which are arranged sequentially from the n-type source region 322n toward the n-type drain region 323n in the second direction Y. For example, the LV-p-type first section 54 may correspond to the p-type source end region 327n, the LV-p-type second section 55 may correspond to the p-type end low concentration region 329n, and the LV-p-type third section 56 may correspond to the p-type drain end region 328n. The concentration profile 53 can be measured by, for example, a method such as SMM (Scanning Microwave Microscopy) or SCM (Scanning Capacitance Microscopy).

Referring to FIGS. 8 and 9, if the first width W_{LV-n1} of the LV-n-side first channel region 326n in the second direction Y and the second width W_{LV-n2} of the LV-n-side second channel region 330n in the second direction Y are compared with each other, the second width W_{LV-n2} is relatively large. For example, the first width W_{LV-n1} may be 0.05 μm or more and 10.0 μm or less, and the second width W_{LV-n2} may be 0.1 μm or more and 10.0 μm or less.

Further, an LV-p-type back gate region 44n is formed on the surface layer portion of the LV-p-type well 321n. The LV-p-type back gate region 44n is electrically connected to the LV-p-type well 321n.

### [Common Structure of Medium Withstand Voltage CMOS Transistor 31 and Low Withstand Voltage CMOS Transistor 32]

An interlayer insulating film 49 is formed on the first main surface 61 of the epitaxial layer 6. The interlayer insulating film 49 may be made of, for example, silicon oxide (SiO₂), silicon nitride (SiN), or the like. In this embodiment, the interlayer insulating film 49 is made of silicon oxide.

In the interlayer insulating film 49, an MV-p-side source contact 57p, an MV-p-side drain contact 58p, an MV-n-side source contact 57n, an MV-n-side drain contact 58n, an LV-p-side source contact 59p, an LV-p-side drain contact 60p, an LV-n-side source contact 59n, and an LV-n-side drain contact 60n are formed. These contacts 57p to 60p and 57n to 60n are embedded in the interlayer insulating film 49. The contacts 57p to 60p and 57n to 60n may be made of a metallic material such as tungsten (W) or the like. Referring to FIG. 1, the contacts 57p to 60p and 57n to 60n are respectively formed at intervals along the first direction X.

On the interlayer insulating film 49, an MV-p-side source wiring 63p, an MV-p-side drain wiring 64p, an MV-n-side source wiring 63n, an MV-n-side drain wiring 64n, an LV-p-side source wiring 65p, an LV-p-side drain wiring 66p, an LV-n-side source wiring 65n, and an LV-n-side drain wiring 66n are formed. The wirings 63p to 66p and 63n to 66n may be made of, for example, a metallic material such as aluminum (Al) or the like.

The MV-p-side source wiring 63p is electrically connected to the p-type source region 312p via the MV-p-side source contact 57p. The MV-p-side drain wiring 64p is electrically connected to the p-type drain region 313p via the MV-p-side drain contact 58p. The MV-n-side source wiring 63n is electrically connected to the n-type source region 312n via the MV-n-side source contact 57n. The MV-n-side drain wiring 64n is electrically connected to the n-type drain region 313n via the MV-n-side drain contact 58n.

The LV-p-side source wiring 65p is electrically connected to the p-type source region 322p via the LV-p-side source contact 59p. The LV-p-side drain wiring 66p is electrically connected to the p-type drain region 323p via the LV-p-side drain contact 60p. The LV-n-side source wiring 65n is electrically connected to the n-type source region 322n via the LV-n-side source contact 59n. The LV-n-side drain wiring 66n is electrically connected to the n-type drain region 323n via the LV-n-side drain contact 60n.

### [Effect of Semiconductor Device 1]

According to the semiconductor device 1 of the present disclosure, as shown in FIGS. 3 and 4, at the first end portion 71p and the second end portion 72p of the MV-p-side active region 7p, the n-type source end region 317p and the n-type drain end region 318p, which extend integrally along the second direction Y from each of the p-type source region 312p and the p-type drain region 313p, are formed. Thus, as shown in FIGS. 2 and 3, if the first width W_{MV-p1} of the MV-p-side first channel region 316p in the second direction Y and the second width W_{MV-p2} of the MV-p-side second channel region 320p in the second direction Y are compared with each other, the second width W_{MV-p2} is relatively large. Further, as shown in FIG. 7A, the concentration profile 20 of the n-type impurity in the MV-p-side second channel region 320p includes the MV-n-type first section 16, the MV-n-type second section 17 changing within an impurity concentration lower than the impurity concentration in the MV-n-type first section 16, and the MV-n-type third section 18 changing within an impurity concentration higher than the impurity concentration in the MV-n-type second section 17, which are arranged sequentially from the p-type source region 312p toward the p-type drain region 313p in the second direction Y. As a result, the gate threshold voltage at the first end portion 71p and the second end portion 72p of the MV-p-side active region 7p can be made higher than the gate threshold voltage at the central portion 73p of the MV-p-side active region 7p. Therefore, when the gate voltage is applied, the MV-p-side first channel region 316p can be formed preferentially or stably. As a result, it is possible to suppress a hump phenomenon from occurring in the drain current-gate voltage (Ids-Vgs) characteristic.

Further, as shown in FIGS. 3 and 5, at the first end portion 71n and the second end portion 72n of the MV-p-side active region 7n, the p-type source end region 317n and the p-type drain end region 318n, which extend integrally along the second direction Y from each of the n-type source region 312n and the n-type drain region 313n, are formed. Thus, as shown in FIGS. 2 and 3, if the first width W_{MV-n1} of the MV-n-side first channel region 316n in the second direction Y and the second width W_{MV-n2} of the MV-n-side second channel region 320n in the second direction Y are compared with each other, the second width W_{MV-n2} is relatively large. Further, as shown in FIG. 7B, the concentration profile 22 of the n-type impurity in the MV-n-side second channel region 320n includes the MV-p-type first section 23, the MV-p-type second section 24 changing within an impurity concentration lower than the impurity concentration in the MV-p-type first section 23, and the MV-p-type third section 25 changing within an impurity concentration higher than the impurity concentration in the MV-p-type second section 24, which are arranged sequentially from the n-type source region 312n toward the n-type drain region 313n in the second direction Y. As a result, the gate threshold voltage at the first end portion 71n and the second end portion 72n of the MV-n-side active region 7n can be made higher than the gate threshold voltage at the central portion 73n of the MV-n-side active region 7n. Therefore, when the gate voltage is applied, the MV-n-side first channel region 316n can be formed preferentially or stably. As a result, it is possible to suppress the occurrence of a hump phenomenon in the drain current-gate voltage (Ids-Vgs) characteristic.

Further, as shown in FIGS. 9 and 10, at the first end portion 27p and the second end portion 28p of the LV-p-side active region 26p, the n-type source end region 327p and the n-type drain end region 328p, which extend integrally along the second direction Y from each of the p-type source region 322p and the p-type drain region 323p, are formed. Thus, as shown in FIGS. 8 and 9, if the first width W_{LV-p1} of the LV-p-side first channel region 326p in the second direction Y and the second width W_{LV-p2} of the LV-p-side second channel region 330p in the second direction Y are compared with each other, the second width W_{LV-p2} is relatively large. Further, as shown in FIG. 12A, the concentration profile 35 of the n-type impurity in the LV-p-side first channel region 326p includes the LV-n-type first section 36, the LV-n-type second section 37 changing within an impurity concentration lower than the impurity concentration in the LV-n-type first section 36, and the LV-n-type third section 38 changing within an impurity concentration higher than the impurity concentration in the LV-n-type second section 37, which are arranged sequentially from the p-type source region 322p toward the p-type drain region 323p in the second direction Y. As a result, the gate threshold voltage at the first end portion 27p and the second end portion 28p of the LV-p-side active region 26p can be made higher than the gate threshold voltage at the central portion 29p of the LV-p-side active region 26p. Therefore, when the gate voltage is applied, the LV-p-side first channel region 326p can be formed preferentially or stably. As a result, it is possible to suppress a hump phenomenon from occurring in the drain current-gate voltage (Ids-Vgs) characteristic.

Further, as shown in FIGS. 9 and 11, at the first end portion 27n and the second end portion 28n of the LV-n-side active region 26n, the p-type source end region 327n and the p-type drain end region 328n, which extend integrally along the second direction Y from each of the n-type source region 322n and the n-type drain region 323n, are formed. Thus, as shown in FIGS. 8 and 9, if the first width W_{LV-n1} of the LV-n-side first channel region 326n in the second direction Y and the second width W_{LV-n2} of the LV-n-side second channel region 330n in the second direction Y are compared with each other, the second width W_{LV-n2} is relatively large. Further, as shown in FIG. 12B, the concentration profile 53 of the n-type impurity in the LV-n-side second channel region 330n includes the LV-p-type first section 54, the LV-p-type second section 55 changing within an impurity concentration lower than the impurity concentration in the LV-p-type first section 54, and the LV-p-type third section 56 changing within an impurity concentration higher than the impurity concentration in the LV-p-type second section 55, which are arranged sequentially from the n-type source region 322n toward the n-type drain region 323n in the second direction Y. As a result, the gate threshold voltage at the first end portion 27n and the second end portion 28n of the LV-n-side active region 26n can be made higher than the gate threshold voltage at the central portion 29n of the LV-n-side active region 26n. Therefore, when the gate voltage is applied, the LV-n-side first channel region 326n can be formed preferentially or stably. As a result, it is possible to suppress the occurrence of a hump phenomenon in the drain current-gate voltage (Ids-Vgs) characteristic.

As described above, according to the semiconductor device 1 of the present disclosure, in any of the medium withstand voltage p-type channel MOS transistor 31p, the medium withstand voltage n-type channel MOS transistor 31n, the low withstand voltage p-type channel MOS transistor 32p, and the low withstand voltage n-type channel MOS transistor 32n, it is possible to suppress a hump phenomenon from occurring in the drain current-gate voltage (Ids-Vgs) characteristic.

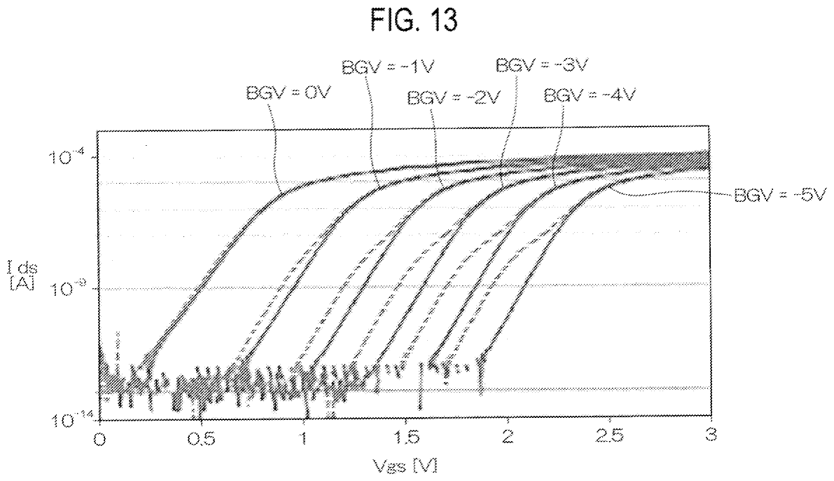

FIG. 13 is a diagram showing static characteristics of the low withstand voltage p-type channel MOS transistor 32p. FIG. 13 shows a change in the drain current Ids with respect to the gate voltage Vgs when the source is grounded and the drain voltage Vds is 0.1 V. The broken line indicates the characteristics when the measures for forming the n-type source end region 327p and the n-type drain end region 328p are not taken, and the solid line indicates the characteristics when the measures for forming the n-type source end region 327p and the n-type drain end region 328p are taken. Further, the characteristic curves indicate the characteristics when the back gate voltage BGV applied to the LV-n-type back gate region 44p is set to 0 V, −1 V, −2 V, −3 V, −4 V, and −5 V.

From FIG. 13, it can be noted that, if the measures for forming the n-type source end region 327p and the n-type drain end region 328p are not taken, a hump as a phenomenon in which a plurality of threshold values appear tends to occur, and this tendency becomes remarkable as the back gate voltage BGV grows high. Although FIG. 13 shows the characteristic example of the low withstand voltage p-type channel MOS transistor 32p, the reduction occurs similarly in the medium withstand voltage p-type channel MOS transistor 31p, the medium withstand voltage n-type channel MOS transistor 31n, and the low withstand voltage n-type channel MOS transistor 32n.

The hump is caused by the formation of the thin film portion 14 (see FIG. 6) corresponding to the recess 13 in the gate oxide film, and the generation of partial electrical connection in the thin film portion 14. Since the LV-p-side first channel region 326p can be formed preferentially or stably in the configuration in which the n-type source end region 327p and the n-type drain end region 328p are formed, the second width W_{LV-p2} of the LV-p-side second channel region 330p is made larger than the first width W_{LV-p1} of the LV-p-side first channel region 326p and thus, the hump can be suppressed. As a result, good static characteristics can be realized even if the back gate voltage is increased.

### [Method of Manufacturing Semiconductor Device 1]

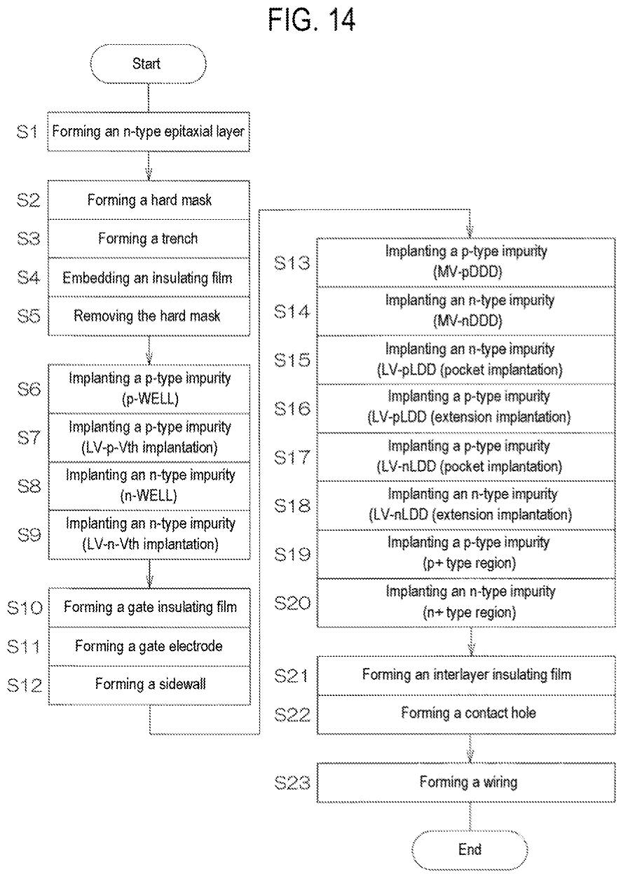

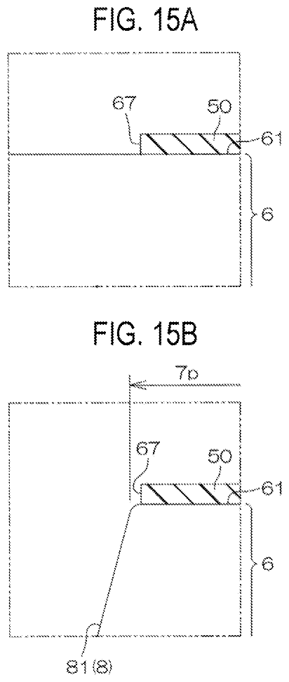

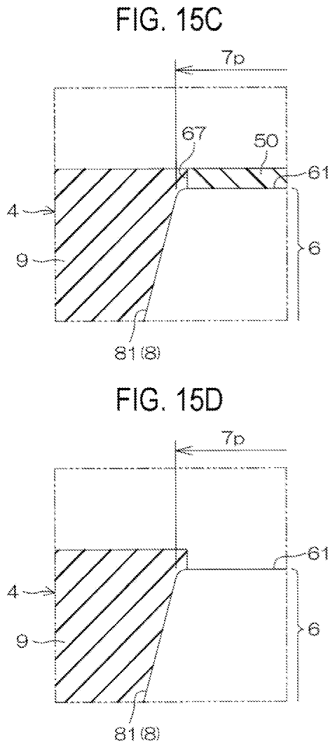

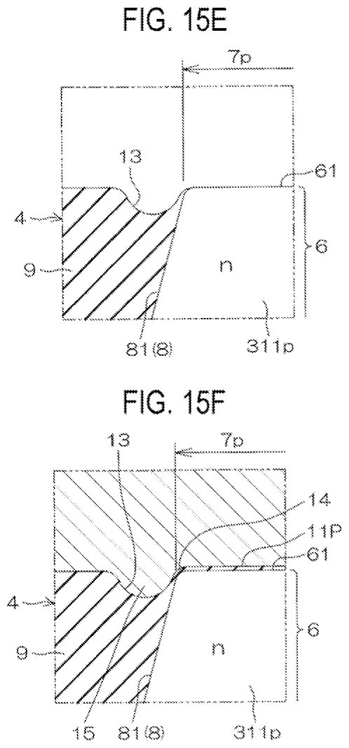

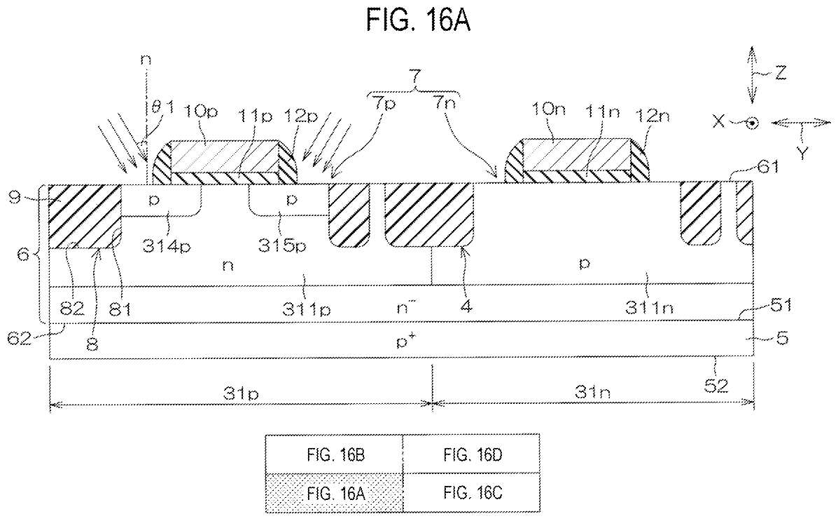

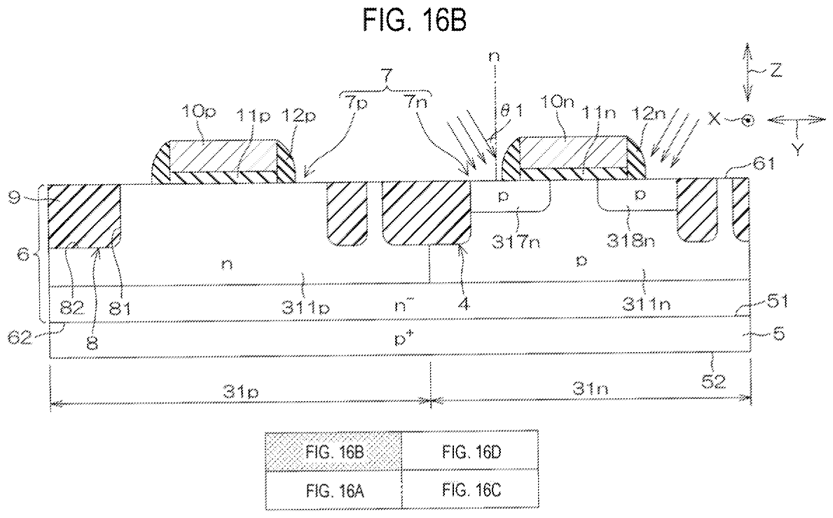

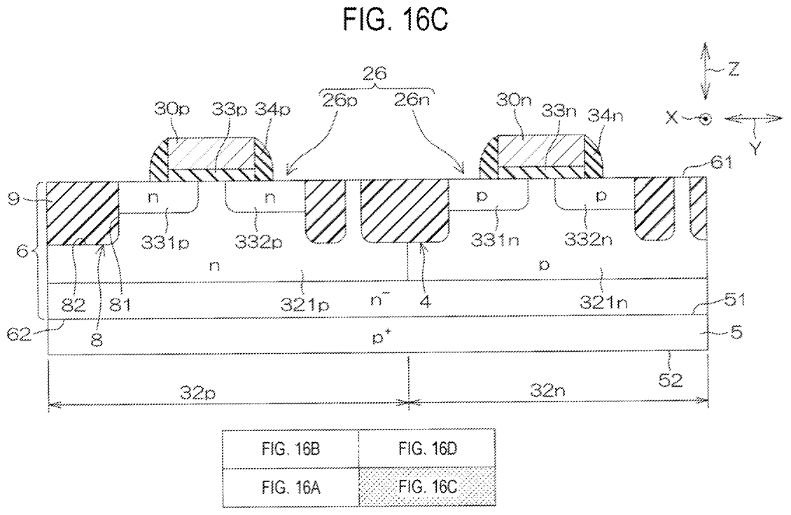

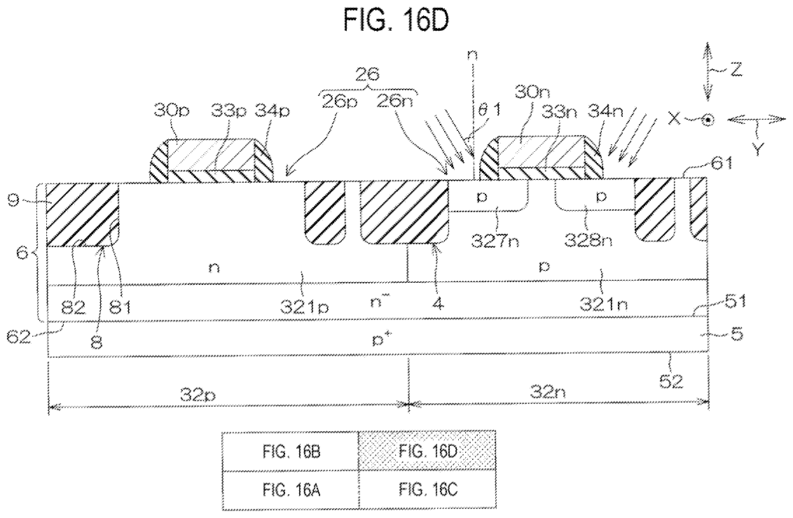

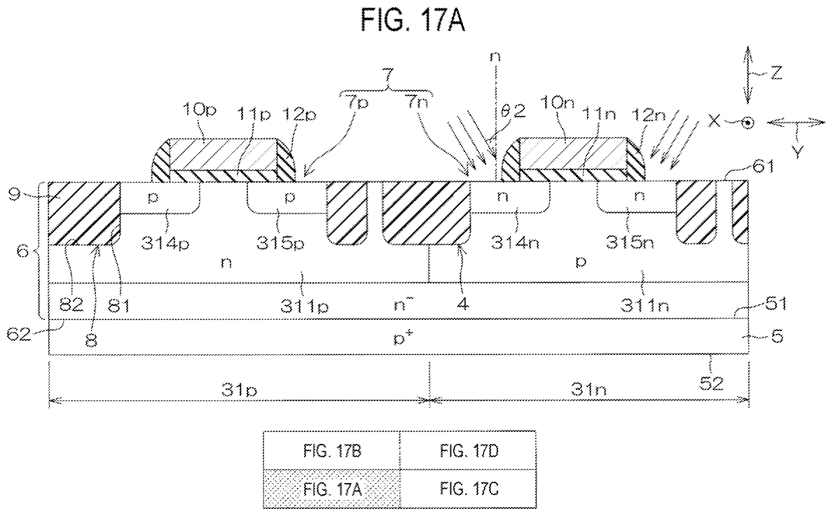

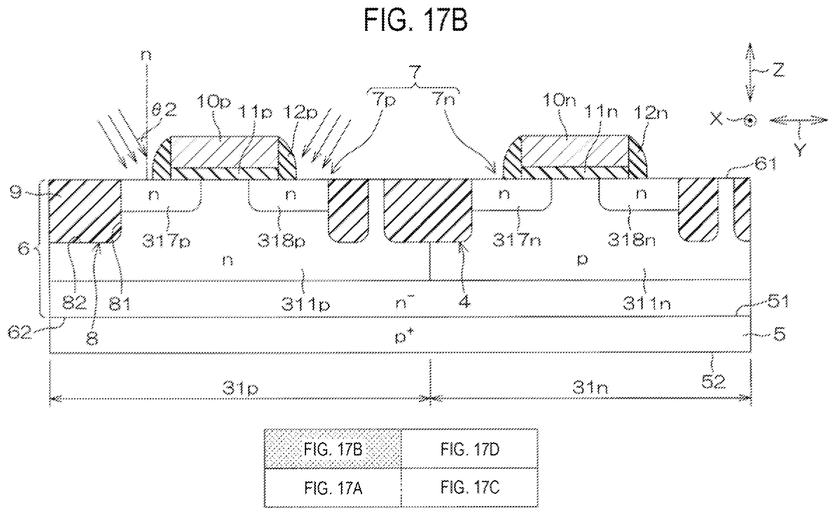

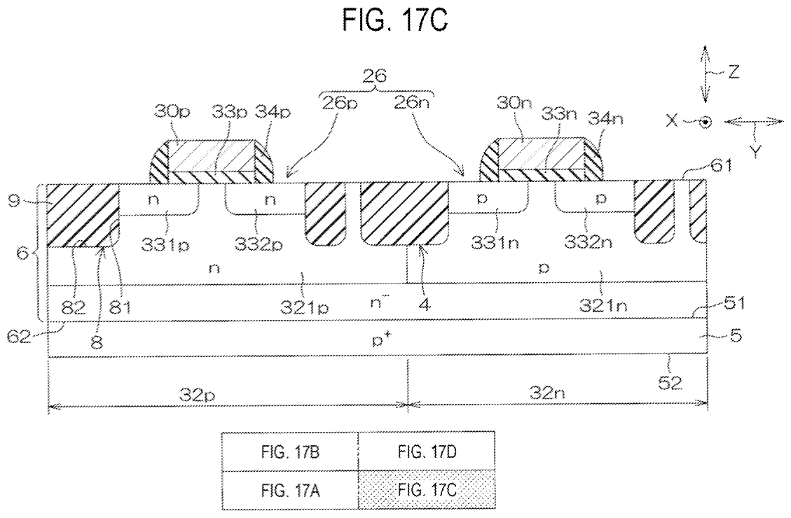

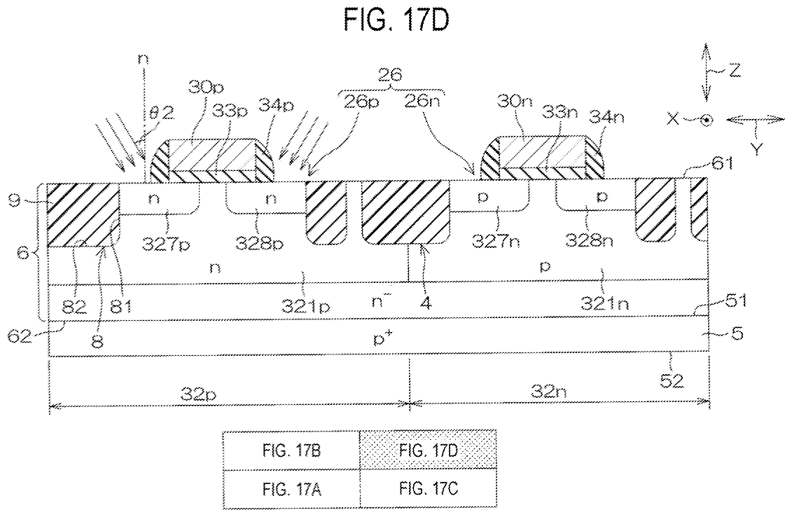

FIG. 14 is a flowchart of a process for manufacturing the semiconductor device 1. FIGS. 15A to 15F are diagrams showing steps related to the formation of the element isolation portion 4 (STI). FIGS. 15A to 15F show a cross section corresponding to FIG. 6. FIGS. 16A to 16D are diagrams showing steps related to the formation of the p-type DDD regions (the p-type source DDD region 314p, the p-type drain DDD region 315p, and the like). FIGS. 17A to 17D are diagrams showing steps related to the formation of the n-type DDD regions (the n-type source DDD region 314n, the n-type drain DDD region 315n, and the like). The figures shown in the lower part of each of FIGS. 16A to 16D and FIGS. 17A to 17D schematically show the relative positional relationship of the cross sections shown in FIGS. 16A to 16D and 17A to 17D with respect to FIG. 1.

In order to manufacture the semiconductor device 1, for example, an n-type epitaxial layer 6 is caused to grow on a p-type semiconductor substrate 5 (S1). Specifically, silicon crystals are caused to epitaxially grow while adding an n-type impurity (e.g., phosphorus). The thickness of the epitaxial layer 6 may be, for example, 0 μm or more and 20 μm or less. Next, an element isolation portion 4 is formed. Specifically, referring to FIG. 15A, a hard mask 50, which is made of an insulating film such as a silicon nitride film (SiN), is formed on the first main surface 61 of the epitaxial layer 6 (S2). The hard mask 50 is formed with an opening 67 corresponding to a region in which the element isolation portion 4 will be formed. Next, referring to FIG. 15B, the epitaxial layer 6 is selectively etched by reactive ion etching (RIE) using the hard mask 50. As a result, a trench 8 is formed (S3). Next, referring to FIG. 15C, an insulating material is formed on the entire surface of the first main surface 61 of the epitaxial layer 6 by, for example, a CVD (Chemical Vapor Deposition) method. Then, a planarization process is performed by a CMP (chemical mechanical polishing) method until the hard mask 50 is exposed. As a result, an embedded insulating layer 9 is formed (S4). Next, referring to FIG. 15D, the hard mask 50 is removed (S5).

Thereafter, an impurity ion implantation step, an impurity ion diffusion step, and the like for forming an MV-p-type well 311n, an MV-n-type well 311p, and the like are performed. Specifically, p-type impurity ions are implanted into the regions for formation of the MV-p-type wells 311n and the LV-p-type wells 321n (S6). At this step, the impurity concentrations of the MV-p-type well 311n and the LV-p-type well 321n are equal to each other. Next, ion implantation is performed to adjust the impurity concentration on the outermost surface of the LV-p-type well 321n. This ion implantation is an ion implantation for adjusting the gate threshold voltage Vth of a low withstand voltage n-type channel MOS transistor 32n, and may be referred to as an LV-p-Vth implantation (S7). That is, the LV-p-type well 321n may be formed by combining the MV-p-type well 311n and the LV-p-Vth implantation. Next, n-type impurity ions are implanted into the regions for formation of the MV-n-type well 311p and the LV-n-type well 321p (S8). At this step, the impurity concentrations of the MV-n-type well 311p and the LV-n-type well 321p are equal to each other. Next, ion implantation is performed to adjust the impurity concentration of the outermost surface of the LV-n-type well 321p. This ion implantation is an ion implantation for adjusting the gate threshold voltage Vth of a low withstand voltage p-type channel MOS transistor 32p, and may be referred to as an LV-n-Vth implantation (S9). That is, the LV-n-type well 321p may be formed by combining the MV-n type well 311p and the LV-n-Vth implantation.

For example, in each of the impurity ion implantation step and the impurity ion diffusion step shown in S6 to S9 above, the epitaxial layer 6 is subjected to a cleaning (light etching) process using hydrofluoric acid. Therefore, the film reduction of the embedded insulating layer 9 (silicon oxide film) occurs. This film reduction proceeds in an isotropic manner, and the epitaxial layer 6 is insoluble in the hydrofluoric acid. Therefore, until a gate insulating film is formed, as shown in FIG. 15E, the corner portion of the embedded insulating layer 9 recedes inward from the upper end edge portion of the trench 8. A recess (divot) 13 is formed at the boundary with the active region (the MV-p-side active region 7p in FIGS. 15B to 15F).

In this state, referring to FIG. 15F, an MV-p-side gate insulating film 11p (MV-n-side gate insulating film 11n, LV-p-side gate insulating film 33p, and LV-n-side gate insulating film 33n) is formed (S10). Next, an MV-p-side gate electrode 10p (MV-n-side gate electrode 10n, LV-p-side gate electrode 30p, and LV-n-side gate electrode 30n) is formed (S11). Therefore, the MV-p-side gate insulating film 11p (MV-n-side gate insulating film 11n, LV-p-side gate insulating film 33p, and LV-n-side gate insulating film 33n) includes a thin film portion 14 having a smaller film thickness than the other portions and formed at a boundary with the trench 8, i.e., at the edge portion of the active region (MV-p-side active region 7p, etc.). This thin film portion 14 causes a decrease in the withstand voltage of the gate insulating film and a defect in the static characteristics of the transistor (such as a hump phenomenon in which a threshold value becomes unstable). After the formation of the gate electrode, a sidewall (MV-p-side sidewall 12p, MV-n-side sidewall 12n, LV-p-side sidewall 34p, and LV-n-side sidewall 34n) is formed around the gate electrode. (S12). Since the MV-p-side gate insulating film 11p and the MV-n-side gate insulating film 11n are different in withstand voltage from the LV-p-side gate insulating film 33p and the LV-n-side gate insulating film 33n, they may be formed in separate steps. For example, the MV-p-side gate insulating film 11p and the MV-n-side gate insulating film 11n may be formed in the same process, and then the LV-p-side gate insulating film 33p and the LV-n-side gate insulating film 33n may be formed.

Next, referring to FIGS. 16A to 16D, an impurity region related to a p-type DDD region is formed. A p-type source DDD region 314p and a p-type drain DDD region 315p of an MV-p-side active region 7p (FIG. 16A), a p-type source end region 317n and a p-type drain end region 318n of an MV-n-side active region 7n (FIG. 16B), and a p-type source end region 327n and a p-type drain end region 328n of an LV-n-side active region 26n (FIG. 16D) are formed in the same step. That is, since the end regions 317n, 318n, 327n and 328n are formed using the photomask used at the time of forming the p-type source DDD region 314p and the p-type drain DDD region 315p, it is not necessary to prepare a dedicated photomask for forming the end regions 317n, 318n, 327n and 328n. Therefore, the end regions 317n, 318n, 327n and 328n can be formed while suppressing an increase in cost. Specifically, p-type impurity ions are implanted into the formation regions of the impurity regions 314p, 315p, 317n, 318n, 327n and 328n related to the p-type DDD region (S13).

Next, referring to FIGS. 17A to 17D, an impurity region related to an n-type DDD region is formed. An n-type source DDD region 314n and an n-type drain DDD region 315n of an MV-n-side active region 7n (FIG. 17A), an n-type source end region 317p and an n-type drain end region 318p of an MV-p-side active region 7p (FIG. 17B), and an n-type source end region 32′7p and an n-type drain end region 328p of an LV-p-side active region 26p (FIG. 17D) are formed in the same step. That is, since the end regions 317p, 318p, 32′7p and 328p are formed using the photomask used at the time of forming the n-type source DDD region 314n and the n-type drain DDD region 315n, it is not necessary to prepare a dedicated photomask for forming the end regions 317p, 318p, 32′7p and 328p. Therefore, the end regions 317p, 318p, 32′7p and 328p can be formed while suppressing an increase in cost. Specifically, n-type impurity ions are implanted into the formation regions of the impurity regions 314n, 315n, 31′7p, 318p, 32′7p and 328p related to the n-type DDD region (S14).

Next, ion implantation is performed to form a p-side source LDD region and a p-side drain LDD region. Specifically, an n-type ion implantation step (S15) for an n-type source pocket implantation region 331p and an n-type drain pocket implantation region 332p is performed, and then a p-type ion implantation step (S16) for a p-type source extension region 324p and a p-type drain extension region 325p is performed. These steps (S15 and S16) may be performed so that the same mask is used and the ions are implanted in a self-aligned manner with respect to the LV-p-side sidewall 34p.

Next, ion implantation is performed to form an n-side source LDD region and an n-side drain LDD region. Specifically, a p-type ion implantation step (S17) for a p-type source pocket implantation region 331n and a p-type drain pocket implantation region 332n is performed, and then an n-type ion implantation step (S18) for an n-type source extension region 324n and an n-type drain extension region 325n is performed. These steps (S17 and S18) may be performed so that the same mask is used and the ions are implanted in a self-aligned manner with respect to the LV-n-side sidewall 34n.

Next, p-type impurity ions are implanted into the formation regions of the p-type source region 312p, the p-type drain region 313p, the MV-p-type back gate region 43n, the p-type source region 322p, the p-type drain region 323p and the LV-p-type back gate region 44n (S19). Next, n-type impurity ions are implanted into the formation regions of the n-type source region 312n, the n-type drain region 313n, the MV-n-type back gate region 43p, the n-type source region 322n, the n-type drain region 323n and the LV-n-type back gate region 44p (S20).

Thereafter, an interlayer insulating film 49 is formed (S21), contact holes for contacts 57p to 60p and 57n to 60n are formed (S22), and wirings 63p to 66p and 63n to 66n are formed (S23). Through the above steps, the semiconductor device 1 provided with the CMOS transistor 3 including the medium withstand voltage CMOS transistor 31 and the low withstand voltage CMOS transistor 32, a DMOS transistor, a bipolar transistor, a passive element, and the like on the common semiconductor substrate 5 is manufactured.

Although embodiments of the present disclosure have been described above, the present disclosure may also be carried out in other embodiments. For example, in the description of the above-described embodiment and the accompanying drawings, the n-type region may be replaced with a p-type region, and the p-type region may be replaced with an n-type region. Further, the above-mentioned medium withstand voltage CMOS transistor 31 may be applied to, for example, a high withstand voltage CMOS transistor having a rated voltage of 7 V or more and 60 V or less. In that case, the MV-p-side gate length L_{MV-pG} and the MV-n-side gate length L_{MV-nG} may be, for example, 1.0 μm or more and 10.0 μm or less as in the HV-p-side gate length and the HV-n-side gate length, respectively. Further, the thickness of the MV-p-side gate insulating film 11p and the thickness of the MV-n-side gate insulating film 11n may be, for example, 250 Å or more and 750 Å or less like the thickness of the HV-p-side gate insulating film and the thickness of the HV-n-side gate insulating film, respectively.

As described above, the embodiments of the present disclosure are exemplary in all respects and should not be construed in a limited manner, and are intended to include modifications in all respects. The features described below as supplementary notes can be extracted from the description in the subject specification and drawings.

### [Supplementary Note 1-1]

A semiconductor device, includes:
a semiconductor layer having a first main surface in which a region for a first element is formed; and
an element isolation portion configured to partition a first active region in the region for the first element, wherein the first element includes:
a first gate electrode extending across the first active region in a first direction;
   a first gate insulating film formed between the first gate electrode and the semiconductor layer;
   a first-conduction-type first source region and a first-conduction-type first drain region, which are formed on a surface layer portion of the first main surface and spaced apart from each other by interposing the first gate electrode in a second direction intersecting the first direction;
   a first-conduction-type first source extension portion and a first-conduction-type first drain extension portion, which extend integrally along the second direction from the first source region and the first drain region, respectively; and
   a second-conduction-type second source extension portion and a second-conduction-type second drain extension portion, which are selectively formed on an end portion of the first active region and extend integrally along the second direction from the first source region and the first drain region, respectively, and
wherein a concentration profile of a second-conduction-type impurity at the end portion of the first active region includes a first section, a second section changing within an impurity concentration lower than an impurity concentration in the first section, and a third section changing within an impurity concentration higher than the impurity concentration in the second section, which are arranged sequentially from the first source region toward the first drain region in the second direction.

According to this configuration, at the end portion of the first active region, the second-conduction-type second source extension portion and the second-conduction-type second drain extension portion extend from the first source region and the first drain region. As a result, the concentration profile of the second-conduction-type impurity at the end portion of the first active region includes the first section, the second section changing within an impurity concentration lower than the impurity concentration in the first section, and the third section changing within an impurity concentration higher than the impurity concentration in the second section, which are arranged sequentially from the first source region toward the first drain region in the second direction.

By forming the second-conduction-type second source extension portion and the second-conduction-type second drain extension portion, the gate threshold voltage at the end portion of the first active region can be made higher than the gate threshold voltage at the portion of the first active region in which the first-conduction-type first source extension portion and the first-conduction-type first drain extension portion are formed. Therefore, when the gate voltage is applied to the gate electrode, the channel extending through the first source extension portion and the first drain extension portion can be formed preferentially and stably. As a result, it is possible to suppress a hump phenomenon from occurring in the drain current-gate voltage (Ids-Vgs) characteristic.

### [Supplementary Note 1-2]

The semiconductor device of Supplementary Note 1-1, further comprises:
a second-conduction-type first channel region formed between the first source extension portion and the first drain extension portion in the second direction, and configured to face the gate electrode; and
a second-conduction-type second channel region formed between the first source region and the first drain region in the second direction at the end portion of the first active region, and configured to face the gate electrode,
wherein a second width of the second channel region in the second direction is larger than a first width of the first channel region in the second direction.

According to this configuration, since the second width (second channel length) of the second channel region is larger than the first width (first channel length) of the first channel region, the channel can be formed preferentially and stably in the first channel region.

### [Supplementary Note 1-3]

In the semiconductor device of Supplementary Note 1-2, the first element has a first rated voltage and includes a second-conduction-type pocket implantation region which covers a bottom portion and a side portion of at least one of the first source extension portion and the first drain extension portion and has an impurity concentration higher than an impurity concentration of the second channel region.

### [Supplementary Note 1-4]

In the semiconductor device of Supplementary Note 1-3, a first gate length, which is a length of the first gate electrode in the second direction, is 0.05 μm or more and 10.0 μm or less, and

the thickness of the first gate insulating film is 10 Å or more and 50 Å or less.

### [Supplementary Note 1-5]

In the semiconductor device of Supplementary Note 1-3 or 1-4, the first rated voltage of the first element is 1.0 V or more and 4.0 V or less.

### [Supplementary Note 1-6]

In the semiconductor device of Supplementary Note 1-2, the first element has a second rated voltage,
wherein the first source extension portion includes a first source DDD (Double Diffused Drain) region having an impurity concentration lower than an impurity concentration of the first source region, and
wherein the first drain extension portion includes a first drain DDD (Double Diffused Drain) region having an impurity concentration lower than the impurity concentration of the first drain region.

### [Supplementary Note 1-7]

In the semiconductor device of Supplementary Note 1-6, a first gate length, which is a length of the first gate electrode in the second direction, is 0.3 μm or more and 10.0 μm or less, and
the thickness of the first gate insulating film is 50 Å or more and 250 Å or less.

### [Supplementary Note 1-8]

In the semiconductor device of Supplementary Note 1-6 or 1-7, the second rated voltage of the first element is 4.0 V or more and 7.0 V or less.

### [Supplementary Note 1-9]

In the semiconductor device of Supplementary Note 1-2, the first element has a third rated voltage,
wherein a first gate length, which is a length of the first gate electrode in the second direction, is 1.0 μm or more and 10.0 μm or less, and
wherein a thickness of the first gate insulating film is 250 Å or more and 750 Å or less.

### [Supplementary Note 1-10]

In the semiconductor device of Supplementary Note 1-9, the third rated voltage of the first element is 7 V or more and 60 V or less.

### [Supplementary Note 1-11]

In the semiconductor device of any one of Supplementary Notes 1-3 to 1-5, the semiconductor layer is formed with a region for a second element having a second rated voltage higher than the first rated voltage,
wherein the element isolation portion is configured to further partition a second active region in the region for the second element,
wherein the second element includes:
a second gate electrode extending across the second active region in the first direction;
a second gate insulating film formed between the second gate electrode and the semiconductor layer;
a first-conduction-type second source region and a first-conduction-type second drain region, which are formed on a surface layer portion of the first main surface and spaced apart from each other by interposing the second gate electrode in a second direction intersecting the first direction;
a first-conduction-type second source DDD (Double Diffused Drain) region extending integrally from the second source region along the second direction and having an impurity concentration lower than an impurity concentration of the second source region;
a first-conduction-type second drain DDD (Double Diffused Drain) region extending integrally from the second drain region along the second direction and having an impurity concentration lower than the impurity concentration of the second drain region; and
a second-conduction-type third source extension and a second-conduction-type third drain extension portion, which are selectively formed at an end portion of the second active region and integrally extend from the second source region and the second drain region, respectively, along the second direction, and
wherein a concentration profile of a second-conduction-type impurity at the end portion of the first active region includes a fourth section, a fifth section changing within an impurity concentration lower than the impurity concentration in the fourth section, and a sixth section changing within an impurity concentration higher than an impurity concentration in the fifth section, which are arranged sequentially from the second source region toward the second drain region in the second direction.

According to this configuration, at the end portion of the second active region, the second-conduction-type third source extension portion and the second-conduction-type third drain extension portion extend from the second source region and the second drain region. As a result, the concentration profile of the second-conduction-type impurity at the end portion of the second active region includes the fourth section, the fifth section changing within an impurity concentration lower than the impurity concentration in the fourth section, and the sixth section changing within an impurity concentration higher than the impurity concentration in the fifth section, which are arranged sequentially from the second source region toward the second drain region in the second direction.

By forming the second-conduction-type third source extension portion and the second-conduction-type third drain extension portion, the gate threshold voltage at the end portion of the second active region can be made higher than the gate threshold voltage at the portion of the second active region in which the first-conduction-type second source DDD region and the first-conduction-type second drain DDD region are formed. Therefore, when the gate voltage is applied to the gate electrode, the channel extending through the second source DDD region and the second drain DDD region can be formed preferentially and stably.

As a result, in both the first active region and the second active region, it is possible to suppress a hump phenomenon from occurring in the drain current-gate voltage (Ids-Vgs) characteristic.

### [Supplementary Note 1-12]

In the semiconductor device of any one of Supplementary Notes 1-1 to 1-11, the element isolation portion includes a trench formed in the semiconductor layer and an embedded insulating layer embedded in the trench, and
the embedded insulating layer includes a recess selectively formed adjacent to an end portion of the first active region in the trench.

### [Supplementary Note 1-13]

In the semiconductor device of Supplementary Note 12, the first gate electrode extends across a boundary between the first active region and the element isolation portion up to the element isolation portion and includes an embedded portion embedded in the recess of the embedded insulating layer.

### [Supplementary Note 1-14]

In the semiconductor device of any one of Supplementary Notes 1-1 to 1-13, the first element includes a CMOS transistor including a p-type channel MOS transistor and an n-type channel MOS transistor, and
the first active region includes a p-side-active region for the p-type channel MOS transistor and an n-side-active region for the n-type channel MOS transistor, which are insulated from each other by the element isolation portion.

### [Supplementary Note 1-15]

A semiconductor device, comprises:
a semiconductor layer having a first main surface in which a region for a first element having a rated voltage of 1.0 V or more and 4.0 V or less is formed; and
an element isolation portion configured to partition a first active region in the region for the first element, the first active region including an end portion arranged adjacent to the element isolation portion and a central portion spaced apart from the end portion,
wherein the first element includes:
   a first gate electrode extending across the first active region in a first direction;
   a first gate insulating film formed between the first gate electrode and the semiconductor layer;
   a first-conduction-type first source region and a first-conduction-type first drain region, which are formed on a surface layer portion of the first main surface and spaced apart from each other by interposing the first gate electrode in a second direction intersecting the first direction;
   a first channel region, which is formed between the first source region and the first drain region in the second direction, at the central portion of the first active region; and
   a second channel region, which is formed between the first source region and the first drain region in the second direction, at the end portion of the first active region, and
wherein a second width of the second channel region in the second direction is larger than a first width of the first channel region in the second direction.

According to this configuration, since the second width (second channel length) of the second channel region is larger than the first width (first channel length) of the first channel region, the channel can be formed preferentially and stably in the first channel region. As a result, it is possible to suppress a hump phenomenon from occurring in the drain current-gate voltage (Ids-Vgs) characteristic.

### [Supplementary Note 1-16]

In the semiconductor device of Supplementary Note 1-15, the semiconductor layer is formed with a region for a second element having a rated voltage of 1.0 V or more and 4.0 V or less,
wherein the element isolation portion is configured to further partition a second active region in the region for the second element, and
wherein the second element includes:
   a second gate electrode extending across the second active region in the first direction;
   a second gate insulating film formed between the second gate electrode and the semiconductor layer; and
   a first-conduction-type second source region and a first-conduction-type second drain region, which are formed on a surface layer portion of the first main surface and spaced apart from each other by interposing the second gate electrode in the second direction.

### [Supplementary Note 1-17]

A method of manufacturing a semiconductor device, includes:
forming an element isolation portion to partition a p-side active region for a p-type channel MOS transistor constituting a CMOS transistor and an n-side active region for an n-type channel MOS transistor constituting the CMOS transistor, in a semiconductor layer having a first main surface;
forming a p-side gate electrode extending across the p-side active region in a first direction;
forming an n-side gate electrode extending across the n-side active region in the first direction;
forming a pair of p-type central regions spaced apart from each other by interposing the p-side gate electrode, and p-type end regions on both sides of an end portion of the n-side gate electrode by implanting a p-type impurity into both sides of the p-side gate electrode in a second direction intersecting the first direction and both sides of the n-side gate electrode at an end portion of the n-side active region in the first direction via a common first mask;
forming a pair of n-type central regions spaced apart from each other by interposing the n-side gate electrode, and n-type end regions on both sides of an end portion of the p-side gate electrode by implanting an n-type impurity into both sides of the n-side gate electrode in the second direction and both sides of the p-side gate electrode at an end portion of the p-side active region in the first direction via a common second mask;
forming a p-type source region and a p-type drain region which are in contact with the p-type central regions and the n-type end regions in the p-side active region; and
forming an n-type source region and an n-type drain region which are in contact with the n-type central regions and the p-type end regions in the n-side active region.

According to the semiconductor device obtained by this method, the n-type end region is formed at the end portion of the p-side active region, and the p-type end region is formed at the end portion of the n-side active region. Therefore, the gate threshold voltage at the end portion of the p-side active region and the end portion of the n-side active region can be selectively increased. As a result, in both the p-side active region and the n-side active region, it is possible to suppress the occurrence of a hump phenomenon in the drain current-gate voltage (Ids-Vgs) characteristic.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device, comprising:
a semiconductor layer having a first main surface in which a region for a first element is formed; and
an element isolation portion configured to partition a first active region in the region for the first element,
wherein the first element includes:
a first gate electrode extending across the first active region in a first direction;
a first gate insulating film formed between the first gate electrode and the semiconductor layer;
a first-conduction-type first source region and a first-conduction-type first drain region, which are formed on a surface layer portion of the first main surface and spaced apart from each other by interposing the first gate electrode in a second direction intersecting the first direction;
a first-conduction-type first source extension portion and a first-conduction-type first drain extension portion, which extend integrally along the second direction from the first source region and the first drain region, respectively; and
a second-conduction-type second source extension portion and a second-conduction-type second drain extension portion, which are selectively formed on an end portion of the first active region and extend integrally along the second direction from the first source region and the first drain region, respectively, and
wherein a concentration profile of a second-conduction-type impurity at the end portion of the first active region includes a first section, a second section changing within an impurity concentration lower than an impurity concentration in the first section, and a third section changing within an impurity concentration higher than an impurity concentration in the second section, which are arranged sequentially from the first source region toward the first drain region in the second direction.

2. The semiconductor device of claim 1, further comprising:
a second-conduction-type first channel region formed between the first source extension portion and the first drain extension portion in the second direction, and configured to face the first gate electrode; and
a second-conduction-type second channel region formed between the first source region and the first drain region in the second direction at the end portion of the first active region, and configured to face the first gate electrode,
wherein a second width of the second channel region in the second direction is larger than a first width of the first channel region in the second direction.

3. The semiconductor device of claim 2, wherein the first element has a first rated voltage and includes a second-conduction-type pocket implantation region which covers a bottom portion and a side portion of at least one of the first source extension portion and the first drain extension portion and has an impurity concentration higher than an impurity concentration of the second channel region.

4. The semiconductor device of claim 3, wherein a first gate length, which is a length of the first gate electrode in the second direction, is 0.05 μm or more and 10.0 μm or less, and
wherein a thickness of the first gate insulating film is 10 Å or more and 50 Å or less.

5. The semiconductor device of claim 3, wherein the first rated voltage of the first element is 1.0 V or more and 4.0 V or less.

6. The semiconductor device of claim 2, wherein the first element has a second rated voltage,
wherein the first source extension portion includes a first source DDD (Double Diffused Drain) region having an impurity concentration lower than an impurity concentration of the first source region, and
wherein the first drain extension portion includes a first drain DDD (Double Diffused Drain) region having an impurity concentration lower than an impurity concentration of the first drain region.

7. The semiconductor device of claim 6, wherein a first gate length, which is a length of the first gate electrode in the second direction, is 0.3 μm or more and 10.0 μm or less, and
wherein a thickness of the first gate insulating film is 50 Å or more and 250 Å or less.

8. The semiconductor device of claim 6, wherein the second rated voltage of the first element is 4.0 V or more and 7.0 V or less.

9. The semiconductor device of claim 2, wherein the first element has a third rated voltage,
wherein a first gate length, which is a length of the first gate electrode in the second direction, is 1.0 μm or more and 10.0 μm or less, and
wherein a thickness of the first gate insulating film is 250 Å or more and 750 Å or less.

10. The semiconductor device of claim 9, wherein the third rated voltage of the first element is 7 V or more and 60 V or less.

11. The semiconductor device of claim 3, wherein the semiconductor layer is formed with a region for a second element having a second rated voltage higher than the first rated voltage,
wherein the element isolation portion is configured to further partition a second active region in the region for the second element,
wherein the second element includes:
a second gate electrode extending across the second active region in the first direction;
a second gate insulating film formed between the second gate electrode and the semiconductor layer;
a first-conduction-type second source region and a first-conduction-type second drain region, which are formed on the surface layer portion of the first main surface and spaced apart from each other by interposing the second gate electrode in the second direction intersecting the first direction;
a first-conduction-type second source DDD (Double Diffused Drain) region extending integrally from the second source region along the second direction and having an impurity concentration lower than an impurity concentration of the second source region;
a first-conduction-type second drain DDD (Double Diffused Drain) region extending integrally from the second drain region along the second direction and having an impurity concentration lower than an impurity concentration of the second drain region; and
a second-conduction-type third source extension and a second-conduction-type third drain extension portion, which are selectively formed at an end portion of the second active region and integrally extend from the second source region and the second drain region, respectively, along the second direction, and
wherein a concentration profile of a second-conduction-type impurity at the end portion of the first active region includes a fourth section, a fifth section changing within an impurity concentration lower than an impurity concentration in the fourth section, and a sixth section changing within an impurity concentration higher than an impurity concentration in the fifth section, which are arranged sequentially from the second source region toward the second drain region in the second direction.

12. The semiconductor device of claim 1, wherein the element isolation portion includes a trench formed in the semiconductor layer and an embedded insulating layer embedded in the trench, and
wherein the embedded insulating layer includes a recess selectively formed adjacent to the end portion of the first active region in the trench.

13. The semiconductor device of claim 12, wherein the first gate electrode extends across a boundary between the first active region and the element isolation portion up to the element isolation portion, and includes an embedded portion embedded in the recess of the embedded insulating layer.

14. The semiconductor device of claim 1, wherein the first element includes a CMOS transistor including a p-type channel MOS transistor and an n-type channel MOS transistor, and
wherein the first active region includes a p-side-active region for the p-type channel MOS transistor and an n-side-active region for the n-type channel MOS transistor, which are insulated from each other by the element isolation portion.

15. A semiconductor device, comprising:
a semiconductor layer having a first main surface in which a region for a first element having a rated voltage of 1.0 V or more and 4.0 V or less is formed; and
an element isolation portion configured to partition a first active region in the region for the first element, the first active region including an end portion adjacent to the element isolation portion and a central portion spaced apart from the end portion,
wherein the first element includes:
a first gate electrode extending across the first active region in a first direction;
a first gate insulating film formed between the first gate electrode and the semiconductor layer;
a first-conduction-type first source region and a first-conduction-type first drain region, which are formed on a surface layer portion of the first main surface and spaced apart from each other by interposing the first gate electrode in a second direction intersecting the first direction;
a first channel region, which is formed between the first source region and the first drain region in the second direction, at the central portion of the first active region; and;
a second channel region, which is formed between the first source region and the first drain region in the second direction, at the end portion of the first active region, and
wherein a second width of the second channel region in the second direction is larger than a first width of the first channel region in the second direction.

16. The semiconductor device of claim 15, wherein the semiconductor layer is formed with a region for a second element having a rated voltage of 1.0 V or more and 4.0 V or less,
wherein the element isolation portion is configured to further partition a second active region in the region for the second element, and
wherein the second element includes:
a second gate electrode extending across the second active region in the first direction;
a second gate insulating film formed between the second gate electrode and the semiconductor layer; and
a first-conduction-type second source region and a first-conduction-type second drain region, which are formed on the surface layer portion of the first main surface and spaced apart from each other by interposing the second gate electrode in the second direction.

17. A method of manufacturing a semiconductor device, comprising:
forming an element isolation portion to partition a p-side active region for a p-type channel MOS transistor constituting a CMOS transistor and an n-side active region for an n-type channel MOS transistor constituting the CMOS transistor, in a semiconductor layer having a first main surface;
forming a p-side gate electrode extending across the p-side active region in a first direction;
forming an n-side gate electrode extending across the n-side active region in the first direction;
forming a pair of p-type central regions spaced apart from each other by interposing the p-side gate electrode, and p-type end regions on both sides of an end portion of the n-side gate electrode by implanting a p-type impurity into both sides of the p-side gate electrode in a second direction intersecting the first direction and both sides of the n-side gate electrode at an end portion of the n-side active region in the first direction via a common first mask;
forming a pair of n-type central regions spaced apart from each other by interposing the n-side gate electrode, and n-type end regions on both sides of an end portion of the p-side gate electrode by implanting an n-type impurity into both sides of the n-side gate electrode in the second direction and both sides of the p-side gate electrode at an end portion of the p-side active region in the first direction via a common second mask;
forming a p-type source region and a p-type drain region which are in contact with the p-type central regions and the n-type end regions in the p-side active region; and
forming an n-type source region and an n-type drain region which are in contact with the n-type central regions and the p-type end regions in the n-side active region.
